(19) United States
(12) Patent Application Publication
(10) Pub. No.: US 2022/0064444 A1
(43) Pub. Date: Mar. 3, 2022

(54) RESIN COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventor: Yuki NARA, Shizuoka (JP)

(73) Assignee: FUJIFILM Corporation, Tokyo (JP)

(21) Appl. No.: 17/521,859

(22) Filed: Nov. 9, 2021

Related U.S. Application Data
(63) Continuation of application No. PCT/JP2020/020442, filed on May 25, 2020.

(30) Foreign Application Priority Data
May 31, 2019 (JP) 2019-102011

(51) Int. Cl. C08L 79/08; C08L 39/00; C08J 5/18; C03C 17/32; C08K 5/00

(52) U.S. Cl. CPC C08L 79/08; C08L 39/00; C08J 5/18; C03C 17/32; G02B 5/20; C08K 5/0025; C08J 2379/08; C08J 2339/00; C08K 5/0041

(57) ABSTRACT

Provided are a resin composition including a coloring material, a resin, and a solvent, in which, in a case where a film having a thickness of 0.60 μm is formed by heating the resin composition at 200° C. for 30 minutes, a rate of change ΔA in an absorbance of the film after performing a heating treatment of the film at 300° C. for 5 hours in a nitrogen atmosphere, which is represented by Expression (1), is 50% or less; a film formed of the resin composition; a color filter; a solid-state imaging element; and an image display device. In the following expression, ΔA is the rate of change in the absorbance of the film after the heating treatment, A1 is a maximum value of an absorbance of the film before the heating treatment in a wavelength range of 400 to 1100 nm, and A2 is an absorbance of the film after the heating treatment, and is an absorbance at a wavelength showing the maximum value of the absorbance of the film before the heating treatment in a wavelength range of 400 to 1100 nm.

ΔA=|100−(A2/A1)×100| (1)

### CROSS-REFERENCE TO RELATED APPLICATIONS

This application is a Continuation of PCT International Application No. PCT/JP2020/020442 filed on May 25, 2020, which claims priority under 35 U.S.C § 119(a) to Japanese Patent Application No. 2019-102011 filed on May 31, 2019. Each of the above application(s) is hereby expressly incorporated by reference, in its entirety, into the present application.

### BACKGROUND OF THE INVENTION

### 1. Field of the Invention

The present invention relates to a resin composition including a pigment, a film, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A film including a pigment, such as a color filter, has been used for the solid-state imaging element. The film including a pigment, such as a color filter, is manufactured by using a resin composition and the like, which includes the pigment, a resin, and a solvent.

JP2017-186530A discloses that a colored resin composition including a predetermined polyimide precursor, a coloring agent, and a solvent is used to manufacture a colored film having excellent light shielding properties and insulating property.

WO2018/061988A discloses that a photosensitive composition including a predetermined polysiloxane compound, a photoacid generator, a coloring agent, and a solvent is used to manufacture a colored pattern.

### SUMMARY OF THE INVENTION

In recent years, in the manufacturing process of a solid-state imaging element, it has been also studied to form a film such as a color filter using a resin composition including a pigment, a resin, and a solvent, and then subject the film to a step requiring a heating treatment at a high temperature (for example, 300° C. or higher).

Therefore, an object of the present invention is to provide a novel resin composition which can expand a process window of the process after manufacturing the film, a film, a color filter, a solid-state imaging element, and an image display device.

The present invention provides the following.

<1> A resin composition comprising:

a coloring material;

a resin; and

a solvent,

in which, in a case where a film having a thickness of 0.60 μm is formed by heating the resin composition at 200° C. for 30 minutes, a rate of change ΔA in an absorbance of the film after performing a heating treatment of the film at 300° C. for 5 hours in a nitrogen atmosphere, which is represented by Expression (1), is 50% or less,

ΔA=|100−(A2/A1)×100| (1)

ΔA is the rate of change in the absorbance of the film after the heating treatment;

A1 is the maximum value of the absorbance of the film before the heating treatment in a wavelength range of 400 to 1100 nm; and

A2 is an absorbance of the film after the heating treatment, and is an absorbance at a wavelength showing the maximum value of the absorbance of the film before the heating treatment in a wavelength range of 400 to 1100 nm.

<2> The resin composition according to <1>,

in which, in the case where a film having a thickness of 0.60 μm is formed by heating the resin composition at 200° C. for 30 minutes, an absolute value of a difference between a wavelength λ1 showing the maximum value of the absorbance of the film in a wavelength range of 400 to 1100 nm and a wavelength λ2 showing the maximum value of the absorbance of the film after the heating treatment at 300° C. for 5 hours in a nitrogen atmosphere is 50 nm or less.

<3> The resin composition according to <1> or <2>,

in which, in the case where a film having a thickness of 0.60 μm is formed by heating the resin composition at 200° C. for 30 minutes, a maximum value of the rate of change in an absorbance of the film after the heating treatment at 300° C. for 5 hours in a nitrogen atmosphere in a wavelength range of 400 to 1100 nm is 30% or less.

<4> The resin composition according to any one of <1> to <3>,

in which a content of the coloring material in a total solid content of the resin composition is 5 mass % or more.

<5> The resin composition according to any one of <1> to <4>,

in which the coloring material is an organic pigment.

<6> The resin composition according to any one of <1> to <5>,

in which the coloring material includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment.

<7> The resin composition according to any one of <1> to <6>,

in which the coloring material includes two or more chromatic coloring materials and a near-infrared absorbing coloring material, or includes a black pigment and a near-infrared absorbing coloring material.

<8> The resin composition according to any one of <1> to <7>,

in which the coloring material includes at least one selected from C. I. Pigment Red 264 or C. I. Pigment Blue 16.

<9> The resin composition according to any one of <1> to <8>,

in which the resin includes at least one resin A selected from a polyimide resin, a polybenzoxazole resin, an epoxy resin, a bismaleimide resin, a silicone resin, a polyarylate resin, a benzoxazine resin, or a precursor of these resins.

<10> The resin composition according to <9>,

in which the resin A is at least one selected from a polyimide resin, a polybenzoxazole resin, or a precursor of these resins.

<11> The resin composition according to <9> or <10>,

in which, in a case where the resin A is applied to a glass substrate and heated at 100° C. for 120 seconds to form a film having a thickness of 0.60 μm, a minimum value of a transmittance of the film at a wavelength of 400 to 1100 nm is 70% or more.

<12> The resin composition according to any one of <9> to <11>,

in which the resin A is included in an amount of 20 mass % or more in components in which the coloring material is excepted from a total solid content of the resin composition.

<13> The resin composition according to any one of <1> to <12>,

in which the resin includes an alkali-soluble resin.

<14> The resin composition according to any one of <1> to <13>, further comprising:

a photopolymerization initiator.

<15> The resin composition according to any one of <1> to <14>,

in which, in a case where the resin composition is applied to a glass substrate and heated at 100° C. for 120 seconds to form a film having a film thickness of 0.6 μm, a maximum value of a transmittance of the film at a wavelength of 400 to 1100 nm is 70% or more, and a minimum value thereof is 30% or less.

<16> The resin composition according to any one of <1> to <15>,

in which the resin composition is used for forming a pattern in a photolithography method.

<17> The resin composition according to any one of <1> to <16>,

in which the resin composition is used for forming a pixel of a color filter.

<18> The resin composition according to any one of <1> to <17>,

in which the resin composition is used for a solid-state imaging element.

<19> A film obtained from the resin composition according to any one of <1> to <18>.

<20> A color filter comprising:

the film according to <19>.

<21> A solid-state imaging element comprising:

the film according to <19>.

<22> An image display device comprising:

the film according to <19>.

According to the present invention, it is possible to provide a novel resin composition which can expand a process window of the process after manufacturing the film, a film, a color filter, a solid-state imaging element, and an image display device.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright line spectrum of a mercury lamp, a far ultraviolet ray represented by excimer laser, an extreme ultraviolet ray (EUV ray), an X-ray, or an electron beam.

In the present specification, a (meth)allyl group represents either or both of allyl and methallyl, “(meth)acrylate” represents either or both of acrylate and methacrylate, “(meth)acryl” represents either or both of acryl and methacryl, and “(meth)acryloyl” represents either or both of acryloyl and methacryloyl.

In the present specification, a weight-average molecular weight and a number-average molecular weight are values in terms of polystyrene through measurement by a gel permeation chromatography (GPC) method.

In the present specification, near-infrared rays denote light having a wavelength in a range of 700 to 2500 nm.

In the present specification, a total solid content denotes the total mass of all the components of the composition excluding a solvent.

In the present specification, the term “step” refers to not only an individual step but also a step which is not clearly distinguishable from another step as long as an effect expected from the step can be achieved.

<Resin Composition>

A resin composition according to an embodiment of the present invention is a resin composition including a coloring material, a resin, and a solvent,

in which, in a case where a film having a thickness of 0.60 μm is formed by heating the resin composition at 200° C. for 30 minutes, a rate of change ΔA in an absorbance of the film after performing a heating treatment of the film at 300° C. for 5 hours in a nitrogen atmosphere, which is represented by Expression (1), is 50% or less.

ΔA=|100−(A2/A1)×100| (1)

ΔA is the rate of change in the absorbance of the film after the heating treatment;

A1 is the maximum value of the absorbance of the film before the heating treatment in a wavelength range of 400 to 1100 nm; and

A2 is an absorbance of the film after the heating treatment, and is an absorbance at a wavelength showing the maximum value of the absorbance of the film before the heating treatment in a wavelength range of 400 to 1100 nm.

With the resin composition according to the embodiment of the present invention, even in a case where a film is manufactured using the resin composition, and the obtained film is subjected to a step requiring a treatment of heating the obtained film at a high temperature of 300° C. or higher, it is possible to suppress variation in spectral characteristics after the heating treatment at high temperature. Therefore, it is possible to expand an applicable range of a heating temperature in steps after manufacturing the film using the resin composition to a higher temperature (for example, 300° C. or higher), and it is possible to expand a process window of the steps after manufacturing the film.

The rate of change ΔA in the absorbance represented by Expression (1) is preferably 45% or less, more preferably 40% or less, and particularly preferably 35% or less.

In addition, in a case where a film having a thickness of 0.60 μm is formed by heating the resin composition according to the embodiment of the present invention at 200° C. for 30 minutes, an absolute value of a difference between a wavelength λ1 showing the maximum value of the absorbance of the film in a wavelength range of 400 to 1100 nm and a wavelength λ2 showing the maximum value of the absorbance of the film after the heating treatment at 300° C. for 5 hours in a nitrogen atmosphere is preferably 50 nm or less, more preferably 45 nm or less, and still more preferably 40 nm or less.

In addition, in a case where a film having a thickness of 0.60 μm is formed by heating the resin composition according to the embodiment of the present invention at 200° C. for 30 minutes, a maximum value of the rate of change in an absorbance of the film after the heating treatment at 300° C. for 5 hours in a nitrogen atmosphere in a wavelength range of 400 to 1100 nm is preferably 30% or less, more preferably 27% or less, and still more preferably 25% or less. The rate of change in the absorbance is a value calculated from Expression (2).

ΔA_{λ}=|100−(A2_{λ}/A1_{λ})×100| (2)

ΔA_{λ} is the rate of change in the absorbance of the film after the heating treatment at a wavelength λ;

A1_{λ} is the absorbance of the film before the heating treatment at the wavelength λ; and

A2_{λ} is the absorbance of the film after the heating treatment at the wavelength λ.

The above-described physical properties can be achieved by adjusting the type and content of the resin or coloring material used.

The resin composition according to the embodiment of the present invention can be used for a color filter, a near-infrared transmitting filter, a near-infrared cut filter, a black matrix, a light shielding film, and the like.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The color filter can be formed using a resin composition including a chromatic coloring material.

Examples of the near-infrared cut filter include a filter having a maximal absorption wavelength in a wavelength range of 700 to 1800 nm. As the near-infrared cut filter, a filter having a maximal absorption wavelength in a wavelength range of 700 to 1300 nm is preferable, and a filter having a maximal absorption wavelength in a wavelength range of 700 to 1100 nm is more preferable. In addition, in the near-infrared cut filter, a transmittance of in the entire wavelength range of 400 to 650 nm is preferably 70% or more, more preferably 80% or more, and still more preferably 90% or more. In addition, the transmittance at at least one point in a wavelength range of 700 to 1800 nm is preferably 20% or less. In addition, in the near-infrared cut filter, absorbance Aₘₐₓ/absorbance A₅₅₀, which is a ratio of an absorbance Aₘₐₓ at a maximal absorption wavelength to an absorbance A₅₅₀ at a wavelength of 550 nm, is preferably 20 to 500, more preferably 50 to 500, still more preferably 70 to 450, and particularly preferably 100 to 400. The near-infrared cut filter can be formed using a resin composition including a near-infrared absorbing coloring material.

The near-infrared transmitting filter is a filter which transmits at least a part of near-infrared rays. The near-infrared transmitting filter may be a filter (transparent film) which transmits both visible light and near-infrared rays, or may be a filter which shields at least a part of visible light and transmits at least a part of near-infrared rays. Preferred examples of the near-infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmitting filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

The resin composition according to the embodiment of the present invention can be preferably used as a resin composition for a color filter. Specifically, the resin composition according to the embodiment of the present invention can be preferably used as a resin composition for forming a pixel of a color filter, and can be more preferably used as a resin composition for forming a red or blue pixel of a color filter. In addition, the resin composition according to the embodiment of the present invention can be preferably used as a resin composition for forming a pixel of a color filter used in a solid-state imaging element.

In a case where the resin composition according to the embodiment of the present invention is applied to a glass substrate and heated at 100° C. for 120 seconds to form a film having a film thickness of 0.6 μm, it is preferable that a maximum value of a transmittance of the film at a wavelength of 400 to 1100 nm is 70% or more (preferably 75% or more, more preferably 80% or more, and still more preferably 85% or more), and a minimum value thereof is 30% or less (preferably 25% or less, more preferably 20% or less, and still more preferably 15% or less). A resin composition capable of forming a film satisfying the above-described spectral characteristics can be particularly preferably used as a resin composition for forming a color filter, a near-infrared transmitting filter, or a near-infrared cut filter.

In addition, the resin composition according to the embodiment of the present invention is also preferably a resin composition used for forming a pattern in a photolithography method. According to this aspect, finely sized pixels can be easily formed. Therefore, the resin composition according to the embodiment of the present invention can be particularly preferably used as a resin composition for forming a pixel of a color filter used in a solid-state imaging element. For example, a resin composition containing a component having a polymerizable group (for example, a resin or polymerizable compound having a polymerizable group) and a photopolymerization initiator can be preferably used as a resin composition used for forming a pattern in a photolithography method. The resin composition for forming a pattern in the photolithography method preferably further contains an alkali-soluble resin.

Hereinafter, the respective components used in the resin composition according to the embodiment of the present invention will be described.

<<Coloring Material>>

The resin composition according to the embodiment of the present invention contains a coloring material. Examples of the coloring material include a white coloring material, a black coloring material, a chromatic coloring material, and a near-infrared absorbing coloring material. In the present invention, the white coloring material includes not only a pure white coloring material but also a bright gray (for example, grayish-white, light gray, and the like) coloring material close to white. In addition, it is preferable that the coloring material includes at least one selected from a chromatic coloring material, a black coloring material, or a near-infrared absorbing coloring material, it is more preferable to include at least one selected from a chromatic coloring material or a near-infrared absorbing coloring material, and it is still more preferable to include a chromatic coloring material. In addition, it is also preferable that the coloring material includes two or more chromatic coloring materials and a near-infrared absorbing coloring material, or includes a black pigment and a near-infrared absorbing coloring material. According to this aspect, the resin composition according to the embodiment of the present invention can be preferably used as a resin composition for forming a near-infrared transmitting filter.

Examples of the coloring material include a dye and a pigment, and from the viewpoint of heat resistance, a pigment is preferable. In addition, the pigment may be an inorganic pigment or an organic pigment, but from the viewpoint of many color variations, ease of dispersion, safety, and the like, an organic pigment is preferable. In addition, it is preferable that the pigment includes at least one selected from a chromatic pigment or a near-infrared absorbing pigment, and it is more preferable to include a chromatic pigment.

In addition, it is preferable that the pigment includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment, it is more preferable to include at least one selected from a phthalocyanine pigment, a diketopyrrolopyrrole pigment, or a pyrrolopyrrole pigment, and it is still more preferable to include a phthalocyanine pigment or a diketopyrrolopyrrole pigment. In addition, from the reason that it is easy to form a film in which spectral characteristics do not easily fluctuate even after heating to a high temperature (for example, 300° C. or higher), the phthalocyanine pigment is preferably a phthalocyanine pigment having no central metal or a phthalocyanine pigment having copper or zinc as a central metal.

In addition, from the reason that it is easy to form a film in which spectral characteristics do not easily fluctuate even after heating to a high temperature (for example, 300° C. or higher), it is preferable that the coloring material included in the resin composition includes at least one selected from a red pigment, a yellow pigment, or a blue pigment, it is more preferable to include at least one selected from a red pigment or a blue pigment, and it is still more preferable to include a blue pigment.

The coloring material included in the resin composition preferably includes a pigment A exhibiting the following requirement 1. By using a coloring material having such characteristics, it is possible to form a film in which spectral characteristics do not easily fluctuate even after heating to a high temperature (for example, 300° C. or higher). The proportion of the pigment A in the total amount of the pigment included in the resin composition is preferably 20 to 100 mass %, more preferably 30 to 100 mass %, and still more preferably 40 to 100 mass %.

Requirement 1)

In a case where a film having a thickness of 0.60 μm is formed by heating, at 200° C. for 30 minutes, a composition which includes 6 mass % of the pigment A, 10 mass % of a resin B-5, and 84 mass % of propylene glycol monomethyl ether acetate, in a case where the film is subjected to a heating treatment at 300° C. for 5 hours in a nitrogen atmosphere, the rate of change ΔA10 in an absorbance of the film after the heating treatment, which is represented by Expression (10), is 50% or less;

ΔA10=|100−(A12/A11)×100| (10)

ΔA10 is the rate of change in the absorbance of the film after the heating treatment;

A11 is the maximum value of the absorbance of the film before the heating treatment in a wavelength range of 400 to 1100 nm;

A12 is the absorbance of the film after the heating treatment, and is the absorbance at the wavelength showing the maximum value of the film before the heating treatment in a wavelength range of 400 to 1100 nm; and

The resin B-5 is a resin having the following structure, in which a numerical value added to a main chain represents a molar ratio, the weight-average molecular weight is 11000, and the acid value is 32 mgKOH/g.

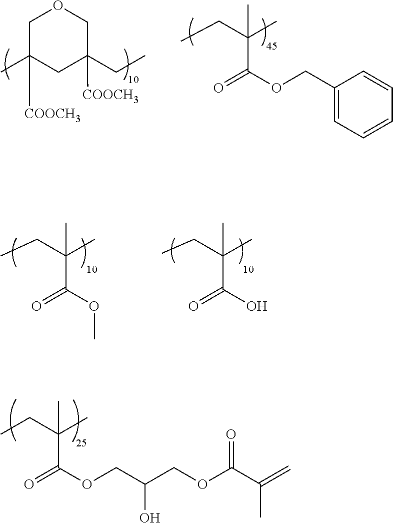

Examples of the pigment A satisfying the above-described requirement 1 include C. I. Pigment Red 254, C. I. Pigment Red 264, Pigment Red 272, Pigment Red 122, Pigment Red 177, C. I. Pigment Blue 15:3, C. I. Pigment Blue 15:4, C. I. Pigment Blue 15:6, and C. I. Pigment Blue 16.

It is preferable that the coloring material included in the resin composition includes at least one selected from C. I. Pigment Red 254, C. I. Pigment Red 264, Pigment Red 272, Pigment Red 122, Pigment Red 177, C. I. Pigment Blue 15:3, C. I. Pigment Blue 15:4, C. I. Pigment Blue 15:6, or C. I. Pigment Blue 16, and it is more preferable to include at least one selected from C. I. Pigment Red 264 or C. I. Pigment Blue 16.

The average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the resin composition is good. In the present invention, the primary particle diameter of the pigment can be determined from an image obtained by observing primary particles of the pigment using a transmission electron microscope. Specifically, a projected area of the primary particles of the pigment is determined, and the corresponding circle-equivalent diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

(Chromatic Coloring Material)

Examples of the chromatic coloring material include a coloring material having a maximal absorption wavelength in a wavelength range of 400 to 700 nm. Examples thereof include a yellow coloring material, an orange coloring material, a red coloring material, a green coloring material, a violet coloring material, and a blue coloring material. From the viewpoint of heat resistance, the chromatic coloring material is preferably a pigment (chromatic pigment), more preferably a red pigment, a yellow pigment, or a blue pigment, and still more preferably a red pigment or a blue pigment. Specific examples of the chromatic pigment include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (monoazo-based), 296 (diazo-based), and the like (all of which are red pigments);

C. I. Pigment Green 7, 10, 36, 37, 58, 59, 62, and 63 (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

Among these chromatic pigments, as the red pigment, from the reason that it is easy to form a film in which spectral characteristics do not easily fluctuate even after heating to a high temperature (for example, 300° C. or higher), C. I. Pigment Red 254, C. I. Pigment Red 264, Pigment Red 272, Pigment Red 122, or Pigment Red 177 is preferable. In addition, as the blue pigment, C. I. Pigment Blue 15:3, C. I. Pigment Blue 15:4, C. I. Pigment Blue 15:6, or C. I. Pigment Blue 16 is preferable.

In addition, as the green coloring material, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green coloring material, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, and the like can also be used.

In addition, as the blue coloring material, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), and a compound represented by Formula (QP2) can also be used.

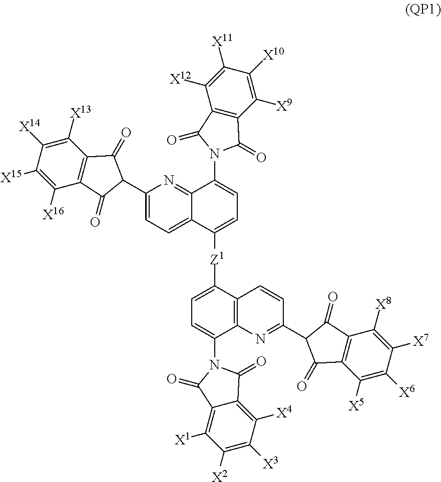

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

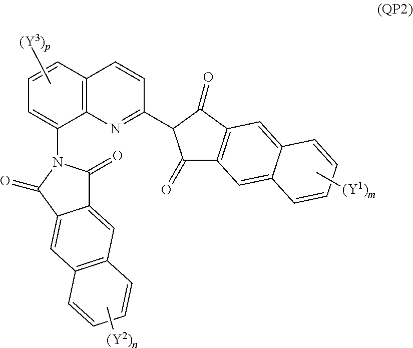

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red coloring material, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

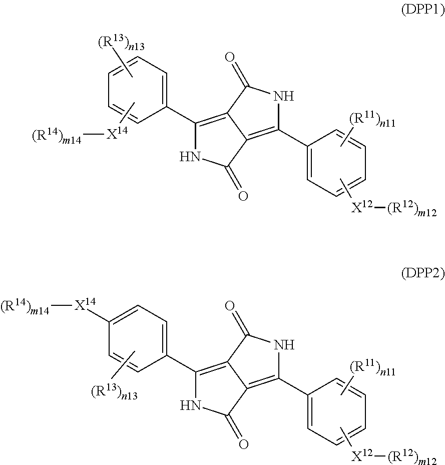

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

The chromatic coloring material may be used in combination of two or more kinds thereof. In addition, in a case where the chromatic coloring material is used in combination of two or more kinds thereof, the combination of two or more chromatic coloring materials may form black. Examples of such a combination include the following aspects (1) to (7). In a case where two or more chromatic coloring materials are included in the resin composition and the combination of two or more chromatic coloring materials forms black, the resin composition according to the embodiment of the present invention can be preferably used as a near-infrared transmitting filter.

(1) aspect in which a red coloring material and a blue coloring material are contained.

(2) aspect in which a red coloring material, a blue coloring material, and a yellow coloring material are contained.

(3) aspect in which a red coloring material, a blue coloring material, a yellow coloring material, and a violet coloring material are contained.

(4) aspect in which a red coloring material, a blue coloring material, a yellow coloring material, a violet coloring material, and a green coloring material are contained.

(5) aspect in which a red coloring material, a blue coloring material, a yellow coloring material, and a green coloring material are contained.

(6) aspect in which a red coloring material, a blue coloring material, and a green coloring material are contained.

(7) aspect in which a yellow coloring material and a violet coloring material are contained.

(White Coloring Material)

Examples of the white coloring material include inorganic pigments (white pigments) such as titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published on Jun. 25, 1991, published by Gihodo Shuppan Co., Ltd.” can also be used.

The white pigment is not limited to a compound formed of a single inorganic substance, and may be particles combined with other materials. For example, it is preferable to use a particle having a pore or other materials therein, a particle having a large number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraph Nos. 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

(Black Coloring Material)

The black coloring material is not particularly limited, and a known black coloring material can be used. Examples thereof include inorganic pigments (black pigments) such as carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

In addition, as the black coloring material, organic black coloring materials such as a bisbenzofuranone compound, an azomethine compound, a perylene compound, and an azo compound can also be used. Examples of the bisbenzofuranone compound include the compounds described in JP2010-534726A, JP2012-515233A, JP2012-515234A, and the like, and the bisbenzofuranone compound is available, for example, as “Irgaphor Black” manufactured by BASF. Examples of the perylene compound include compounds described in paragraph Nos. 0016 to 0020 of JP2017-226821A, and C. I. Pigment Black 31 and 32. Examples of the azomethine compound include the compounds described in JP1989-170601A (JP-1401-170601A) and JP1990-034664A (JP-H02-034664A), and the azomethine compound is available, for example, “CHROMOFINE BLACK A1103” manufactured by Dainichiseika Color & Chemicals Mfg. Co., Ltd.

(Near-Infrared Absorbing Coloring Material)

The near-infrared absorbing coloring material is preferably a pigment, and more preferably an organic pigment. In addition, the near-infrared absorbing coloring material preferably has a maximal absorption wavelength in a wavelength range of more than 700 nm and 1400 nm or less. In addition, the maximal absorption wavelength of the near-infrared absorbing coloring material is preferably 1200 nm or less, more preferably 1000 nm or less, and still more preferably 950 nm or less. In addition, in the near-infrared absorbing coloring material, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing coloring material excellent in visible transparency and near-infrared shielding properties can be obtained. In the present invention, the maximal absorption wavelength of the near-infrared absorbing coloring material and values of absorbance at each wavelength are values obtained from an absorption spectrum of a film formed by using a resin composition including the near-infrared absorbing coloring material.

The near-infrared absorbing coloring material is not particularly limited, and examples thereof include a pyrrolopyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, and a dithiolene metal complex. Examples of the pyrrolopyrrole compound include compounds described in paragraph Nos. 0016 to 0058 of JP2009-263614A, compounds described in paragraph Nos. 0037 to 0052 of JP2011-068731A, and compounds described in paragraph Nos. 0010 to 0033 of WO2015/166873A. Examples of the squarylium compound include compounds described in paragraph Nos. 0044 to 0049 of JP2011-208101A, compounds described in paragraph Nos. 0060 and 0061 of JP6065169B, compounds described in paragraph No. 0040 of WO2016/181987A, compounds described in JP2015-176046A, compounds described in paragraph No. 0072 of WO2016/190162A, compounds described in paragraph Nos. 0196 to 0228 of JP2016-074649A, compounds described in paragraph No. 0124 of JP2017-067963A, compounds described in WO2017/135359A, compounds described in JP2017-114956A, compounds described in JP6197940B, and compounds described in WO2016/120166A. Examples of the cyanine compound include compounds described in paragraph Nos. 0044 and 0045 of JP2009-108267A, compounds described in paragraph Nos. 0026 to 0030 of JP2002-194040A, compounds described in JP2015-172004A, compounds described in JP2015-172102A, compounds described in JP2008-088426A, compounds described in paragraph No. 0090 of WO2016/190162A, and compounds described in JP2017-031394A. Examples of the croconium compound include compounds described in JP2017-082029A. Examples of the iminium compound include compounds described in JP2008-528706A, compounds described in JP2012-012399A, compounds described in JP2007-092060A, and compounds described in paragraph Nos. 0048 to 0063 of WO2018/043564A. Examples of the phthalocyanine compound include compounds described in paragraph No. 0093 of JP2012-077153A, oxytitanium phthalocyanine compound described in JP2006-343631A, compounds described in paragraph Nos. 0013 to 0029 of JP2013-195480A, and vanadium phthalocyanine compounds described in JP6081771B. Examples of the naphthalocyanine compound include compounds described in paragraph No. 0093 of JP2012-077153A. Examples of the dithiolene metal complex include compounds described in JP5733804B.

In addition, as the near-infrared absorbing coloring material, squarylium compounds described in JP2017-197437A, squarylium compounds described in JP2017-025311A, squarylium compounds described in WO2016/154782A, squarylium compounds described in JP5884953B, squarylium compounds described in JP6036689B, squarylium compounds described in JP5810604B, squarylium compounds described in paragraph Nos. 0090 to 0107 of WO2017/213047A, pyrrole ring-containing compounds described in paragraph Nos. 0019 to 0075 of JP2018-054760A, pyrrole ring-containing compounds described in paragraph Nos. 0078 to 0082 of JP2018-040955A, pyrrole ring-containing compounds described in paragraph Nos. 0043 to 0069 of JP2018-002773A, squarylium compounds having an aromatic ring at the α-amide position described in paragraph Nos. 0024 to 0086 of JP2018-041047A, amide-linked squarylium compounds described in JP2017-179131A, compounds having a pyrrole bis-type squarylium skeleton or a croconium skeleton described in JP2017-141215A, dihydrocarbazole bis-type squarylium compounds described in JP2017-082029, asymmetric compounds described in paragraph Nos. 0027 to 0114 of JP2017-068120A, pyrrole ring-containing compounds (carbazole type) described in JP2017-067963A, phthalocyanine compounds described in JP6251530B, and the like can also be used.

The content of the coloring material in the total solid content of the resin composition is preferably 5 mass % or more, more preferably 10 mass % or more, still more preferably 15 mass % or more, and even more preferably 20 mass % or more. The upper limit is preferably 90 mass % or less, more preferably 80 mass % or less, and still more preferably 70 mass % or less.

In addition, the content of the pigment in the total solid content of the resin composition is preferably 5 mass % or more, more preferably 10 mass % or more, still more preferably 15 mass % or more, and even more preferably 20 mass % or more. The upper limit is preferably 90 mass % or less, more preferably 80 mass % or less, and still more preferably 70 mass % or less.

In addition, the content of the dye in the coloring material is preferably 50 mass % or less, more preferably 40 mass % or less, and still more preferably 30 mass % or less.

In addition, from the reason that it is easy to more effectively suppress the change in film thickness in a case where the obtained film is heated to a high temperature, it is also preferable that the resin composition according to the embodiment of the present invention does not substantially include the dye. The case where the resin composition according to the embodiment of the present invention does not substantially include the dye means that the content of the dye in the total solid content of the resin composition according to the embodiment of the present invention is preferably 0.1 mass % or less, more preferably 0.05 mass % or less, and particularly preferably 0 mass %.

The resin composition according to the embodiment of the present invention contains a resin. The resin is blended in, for example, an application for dispersing particles such as a pigment in the resin composition or an application as a binder. Mainly, a resin which is used for dispersing particles such as a pigment is also referred to as a dispersant. However, such applications of the resin are only exemplary, and the resin can also be used for other purposes in addition to such applications.

It is preferable that the resin included in the resin composition according to the embodiment of the present invention includes an alkali-soluble resin. As the alkali-soluble resin, a resin having an acid group is preferable. Examples of the acid group include a phenolic hydroxy group, a carboxy group, a sulfo group, a phosphoric acid group, and a phosphate group. The alkali-soluble resin may be a resin A described below, or may be a resin other than the resin A.

(Resin A)

It is preferable that the resin composition according to the embodiment of the present invention includes at least one resin A selected from a polyimide resin, a polybenzoxazole resin, an epoxy resin, a bismaleimide resin, a silicone resin, a polyarylate resin, a benzoxazine resin, or a precursor of these resins. In addition, a copolymer of (meth)acrylamide and styrene is also suitably used. In a case where the resin composition according to the embodiment of the present invention includes the resin A, it is easy to form a film having excellent heat resistance, and it is easy to suppress film contraction and discoloration after heating. In addition, since it is easy to form a film which does not easily cause yellowing due to heating, for example, in a case where the resin composition according to the embodiment of the present invention is used to form a blue pixel in a color filter, it is possible to suppress the yellowing due to heating of the blue pixel, and it is possible to effectively suppress variation in spectral characteristics due to heating. Further, in a case where an inorganic film on a surface of the film obtained using the resin composition, it is also possible to more effectively suppress the occurrence of cracks in the inorganic film even in a case where the film in which the inorganic film is formed on the surface is heated to a high temperature of 300° C. or higher. In particular, in a case where the resin A is included in an amount of 20 mass % or more in components in which the coloring material is excepted from a total solid content of the resin composition, such an effect can be remarkably obtained. The resin A is preferably a polyimide resin, a precursor of a polyimide resin, a polybenzoxazole resin, a precursor of a polybenzoxazole resin, an epoxy resin, a bismaleimide resin, or a silicone resin, and from the reason that heat resistance is good and contraction after heating is small, it is more preferable to be at least one selected from a polyimide resin, a polybenzoxazole resin, or a precursor of these resins, and it is still more preferable to be a precursor of a polyimide resin or a precursor of a polybenzoxazole resin.

In a case where the above-described resin A is applied to a glass substrate and heated at 100° C. for 120 seconds to form a film having a thickness of 0.60 μm, the minimum value of the transmittance of the film at a wavelength of 400 to 1100 nm is preferably 70% or more, more preferably 75% or more, still more preferably 80% or more, and particularly preferably 85% or more. By using the resin A having such spectral characteristics, the spectral characteristics of the film formed by using the resin composition can be more excellent.

[Polyimide Precursor]

Examples of the precursor of the polyimide resin (hereinafter, also referred to as a polyimide precursor) include compounds including a constitutional unit represented by Formula (PIA-1).

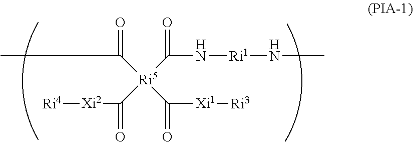

Ri¹ represents a divalent organic group, Ri⁵ represents a tetravalent organic group, Ri³ and Ri⁴ each independently represent a hydrogen atom or a monovalent organic group, Xi¹ and Xi² each independently represent O or NRxi, and Rxi represents a hydrogen atom or a substituent.

Ri¹ represents a divalent organic group. Examples of the divalent organic group include a group including a linear or branched aliphatic hydrocarbon group, a cyclic aliphatic hydrocarbon group, an aromatic hydrocarbon group, or a heterocyclic group, and a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms is preferable, and a group including an aromatic hydrocarbon group having 6 to 20 carbon atoms is more preferable.

Ri¹ is preferably a group derived from diamine. The diamine is preferably a compound including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms, and more preferably a compound including an aromatic hydrocarbon group having 6 to 20 carbon atoms. Specific examples of the diamine include compounds described in paragraphs 0024 to 0029 of WO2017/209177A, the contents of which are incorporated herein by reference.

From the viewpoint of flexibility of the obtained cured film, Ri¹ is preferably represented by —Ar⁰-L⁰-Ar⁰—. Ar⁰'s is each independently an aromatic hydrocarbon group (preferably an aromatic hydrocarbon group having 6 to 22 carbon atoms, more preferably an aromatic hydrocarbon group having 6 to 18 carbon atoms, and particularly preferably an aromatic hydrocarbon group having 6 to 10 carbon atoms), and a phenylene group is preferable. L⁰ represents a single bond or a divalent linking group. As the divalent linking group, an aliphatic hydrocarbon group having 1 to 10 carbon atoms, which may be substituted with a fluorine atom, or a group selected from —O—, —C(═O)—, —S—, —S(═O)₂—, —NHCO—, and a combination thereof is preferable, an alkylene group having 1 to 3 carbon atoms, which may be substituted with a fluorine atom, or a group selected from —O—, —C(═O)—, —S—, and —SO₂— is more preferable, and —CH₂—, —O—, —S—, —SO₂—, —C(CF₃)₂—, or —C(CH₃)₂— is still more preferable.

As the tetravalent organic group represented by Ri⁵, a group including an aromatic ring is preferable, and a group represented by Formula (Ri⁵-1) of Formula (Ri⁵-2) is more preferable.

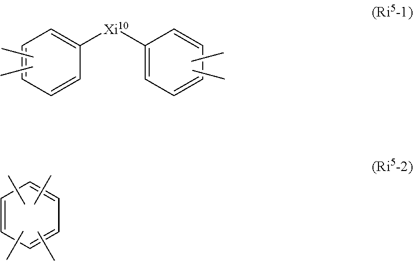

Xi¹⁰ represents a single bond or a divalent linking group. As the divalent linking group, an aliphatic hydrocarbon group having 1 to 10 carbon atoms, which may be substituted with a fluorine atom, or a group selected from —O—, —C(═O)—, —S—, —S(═O)₂—, —NHCO—, and a combination thereof is preferable, an alkylene group having 1 to 3 carbon atoms, which may be substituted with a fluorine atom, or a group selected from —O—, —C(═O)—, —S—, and —SO₂— is more preferable, and —CH₂—, —O—, —S—, —SO₂—, —C(CF₃)₂—, or —C(CH₃)₂— is still more preferable.

Specific examples of the tetravalent organic group represented by Ri⁵ include a tetracarboxylic acid residue remaining after removing an acid dianhydride group from a tetracarboxylic dianhydride. The tetracarboxylic dianhydride may be used singly or two or more kinds thereof may be used. Specific examples of the tetracarboxylic dianhydride include compounds described in paragraphs 0035 to 0037 of WO2017/209177A, the contents of which are incorporated herein by reference.

Ri³ and Ri⁴ each independently represent a hydrogen atom or a monovalent organic group. Examples of the monovalent organic group include a polymerizable group, an acid-decomposable group, a hydrocarbon group, and a heterocyclic group. It is preferable that at least one of Ri³ or Ri⁴ is a polymerizable group, and it is more preferable that both are polymerizable groups. In a case of using a polyimide precursor including a polymerizable group, a film having more excellent characteristics can be easily obtained. In addition, in a case where the resin composition according to the embodiment of the present invention includes a photopolymerization initiator, the resin composition according to the embodiment of the present invention can be a resin composition having excellent pattern forming property in the photolithography method.

As the polymerizable group represented by Ri³ and Ri⁴, a radically polymerizable group is preferable. The radically polymerizable group is a group capable of undergoing a crosslinking reaction by an action of a radical, and preferred examples thereof include an ethylenically unsaturated bond-containing group. Examples of the ethylenically unsaturated bond-containing group include a vinyl group, an allyl group, a (meth)acryloyl group, and a group represented by Formula (III).

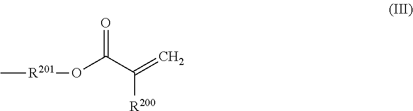

In Formula (III), R²⁰⁰ represents a hydrogen atom or a methyl group, a methyl group is more preferable.

R²⁰¹ in Formula (III) represents an alkylene group having 2 to 12 carbon atoms, —CH₂CH(OH)CH₂—, or a (poly)oxyalkylene group having 4 to 30 carbon atoms (the number of carbon atoms in the alkylene group is preferably 1 to 12, more preferably 1 to 6, and particularly preferably 1 to 3; the repetition number is preferably 1 to 12, more preferably 1 to 6, and particularly preferably 1 to 3). The (poly)oxyalkylene group means an oxyalkylene group or a polyoxyalkylene group. Suitable examples of R²⁰¹ include an ethylene group, a propylene group, a trimethylene group, a tetramethylene group, a 1,2-butanediyl group, a 1,3-butanediyl group, a pentamethylene group, a hexamethylene group, an octamethylene group, a dodecamethylene group, and —CH₂CH(OH)CH₂—, and an ethylene group, a propylene group, a trimethylene group, or —CH₂CH(OH)CH₂— is preferable.

It is particularly preferable that R²⁰⁰ is a methyl group and R²⁰¹ is an ethylene group.

Examples of the acid-decomposable group represented by Ri³ and Ri⁴ include a tertiary alkyl group and an acetal-type acid-decomposable group. Examples of the above-described tertiary alkyl group include a t-butyl group. Examples of the above-described acetal-type acid-decomposable group include a 1-alkoxyalkyl group, a 2-tetrahydrofuranyl group, and a 2-tetrahydropyranyl group.

Examples of the hydrocarbon group represented by Ri³ and Ri⁴ include an alkyl group, an aryl group, and an arylalkyl group. The number of carbon atoms in the alkyl group is preferably 1 to 30, more preferably 1 to 15, and still more preferably 1 to 8. The alkyl group may be linear, branched, or cyclic, and is preferably linear or branched. The number of carbon atoms in the aryl group is preferably 6 to 30, more preferably 6 to 25, and still more preferably 6 to 12. The number of carbon atoms in the arylalkyl group is preferably 7 to 30, more preferably 7 to 25, and still more preferably 7 to 12.

The heterocyclic group represented by Ri³ and Ri⁴ may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and heterocyclic group represented by Ri³ and Ri⁴ may have a substituent or may be unsubstituted. Examples of the substituent include acid groups such as a hydroxy group, a carboxy group, a sulfo group, a phosphoric acid group, and a phosphate group; groups in which these acid groups are protected by an acid-decomposable group; and polymerizable groups. The acid-decomposable group in the groups in which the acid groups are protected by an acid-decomposable group, and the polymerizable group have the same meanings as described above.

Xi¹ and Xi² each independently represent O or NRxi, in which Rxi represents a hydrogen atom or a substituent. Examples of the substituent represented by Rxi include an alkyl group, an aryl group, an alkoxy group, an aryloxy group, and an acyl group. Rxi is preferably a hydrogen atom. Xi¹ and Xi² are preferably O.

In the polyimide precursor, the constitutional unit represented by Formula (PIA-1) may be one kind or two or more kinds. In addition, the polyimide precursor may include a structural isomer of the constitutional unit represented by Formula (PIA-1). In addition, the polyimide precursor may include other types of constitutional units in addition to the constitutional unit represented by Formula (PIA-1).

As one embodiment of the polyimide precursor, a polyimide precursor in which 50 mol % or more, still 70 mol % or more, particularly 90 mol % or more of all constitutional units are the constitutional unit represented by Formula (PIA-1) is mentioned.

As the polyimide precursor, polyimide precursors described in paragraph Nos. 0015 to 0029 of JP2017-186530A, paragraph Nos. 0030 to 0036 of JP2019-023728A, and paragraph Nos. 0029 to 0035 of JP2019-045865A can also be used, the contents of which are incorporated herein by reference.

The weight-average molecular weight (Mw) of the polyimide precursor is preferably 2000 to 500000, more preferably 5000 to 100000, and still more preferably 10000 to 50000. In addition, the number-average molecular weight (Mn) thereof is preferably 800 to 250000, more preferably 2000 to 50000, and still more preferably 4000 to 25000.

The degree of dispersion of the molecular weight of the polyimide precursor is preferably 1.5 to 3.5 and more preferably 2 to 3.

[Polyimide Resin]

Examples of the polyimide resin include compounds obtained by cyclizing a precursor of a polyimide resin (polyimide precursor). Examples of the polyimide precursor include those described above. In addition, it is also preferable that the polyimide resin has at least one group selected from a carboxy group, a sulfo group, a phosphoric acid group, or a phosphate group in at least one of the main chain or the side chain. According to this aspect, a polyimide resin having excellent solubility in an alkali developer can be obtained.

[Polybenzoxazole Precursor]

Examples of the precursor of the polybenzoxazole resin (hereinafter, also referred to as a polybenzoxazole precursor) include compounds including a constitutional unit represented by Formula (PBO-1).

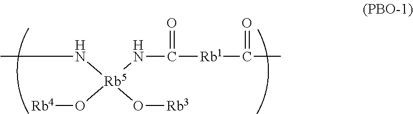

Rb¹ represents a divalent organic group, Rb⁵ represents a tetravalent organic group, and Rb³ and Rb⁴ each independently represent a hydrogen atom or a monovalent organic group.

Examples of the divalent organic group represented by Rb¹ in Formula (PBO-1) include a group including a linear or branched aliphatic hydrocarbon group, a cyclic aliphatic hydrocarbon group, an aromatic hydrocarbon group, or a heterocyclic group, and a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms is preferable, and a linear aliphatic hydrocarbon group having 2 to 20 carbon atoms or a branched aliphatic hydrocarbon group having 3 to 20 carbon atoms is more preferable.

As the tetravalent organic group represented by Rb⁵ in Formula (PBO-1), a group including an aromatic ring is preferable, and the group represented by Formula (Ri⁵-1) of Formula (Ri⁵-2) described above is more preferable.

Examples of the monovalent organic group represented by Rb³ and Rb⁴ in Formula (PBO-1) include a polymerizable group, an acid-decomposable group, a hydrocarbon group, and a heterocyclic group. It is preferable that at least one of Rb³ or Rb⁴ is a polymerizable group, and it is more preferable that both are polymerizable groups. Examples of details of the polymerizable group, acid-decomposable group, hydrocarbon group, and heterocyclic group include those described in the section of monovalent organic group represented Ri³ and Ri⁴ in Formula (PIA-1), and the same applies to the preferred range. In a case of using a polybenzoxazole precursor including a polymerizable group, a film having more excellent characteristics can be easily obtained. In addition, in a case where the resin composition according to the embodiment of the present invention includes a photopolymerization initiator, the resin composition according to the embodiment of the present invention can be a resin composition having excellent pattern forming property in the photolithography method.

In the polybenzoxazole precursor, the constitutional unit represented by Formula (PBO-1) may be one kind or two or more kinds. In addition, the polybenzoxazole precursor may include a structural isomer of the constitutional unit represented by Formula (PBO-1). In addition, the polybenzoxazole precursor may include other types of constitutional units in addition to the constitutional unit represented by Formula (PBO-1).

The weight-average molecular weight (Mw) of the polybenzoxazole precursor is preferably 2000 to 500000, more preferably 5000 to 100000, and still more preferably 10000 to 50000. In addition, the number-average molecular weight (Mn) thereof is preferably 800 to 250000, more preferably 2000 to 50000, and still more preferably 4000 to 25000.

The degree of dispersion of the molecular weight of the polybenzoxazole precursor is preferably 1.5 to 3.5 and more preferably 2 to 3.

[Polybenzoxazole Resin]

Examples of the polybenzoxazole resin include compounds obtained by cyclizing a precursor of a polybenzoxazole resin (polybenzoxazole precursor). Examples of the polybenzoxazole precursor include those described above. In addition, it is also preferable that the polybenzoxazole resin has at least one group selected from a carboxy group, a sulfo group, a phosphoric acid group, or a phosphate group in at least one of the main chain or the side chain. According to this aspect, a polybenzoxazole resin having excellent solubility in an alkali developer can be obtained.

[Epoxy Resin]

As the epoxy resin, a compound having two or more epoxy groups in one molecule is preferable. The number of epoxy groups in one molecule is preferably 2 to 10, more preferably 2 to 5, and particularly preferably 3. The epoxy resin is preferably a compound including a benzene ring, and more preferably a compound having a diaryl structure, a triaryl structure, or a tetraaryl structure.

Examples of one aspect of the epoxy resin include a compound represented by Formula (EP-1).

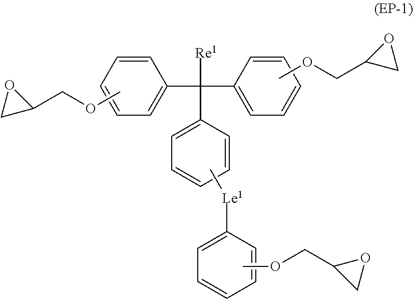

In Formula (EP-1), Re¹ represents a hydrogen atom, an alkyl group, an aryl group, or a halogen atom, and a hydrogen atom, an alkyl group, or a halogen atom is preferable, a hydrogen atom or an alkyl group is more preferable, and an alkyl group is still more preferable.

The number of carbon atoms in the alkyl group represented by Re¹ is preferably 1 to 30 and more preferably 1 to 12. The alkyl group may be linear, branched, or cyclic, and is preferably linear or branched and more preferably linear. The alkyl group may have a substituent, but is preferably unsubstituted.

The number of carbon atoms in the aryl group represented by Re¹ is preferably 6 to 30, more preferably 6 to 25, and still more preferably 6 to 12. The alkyl group and aryl group represented by Re¹ may have a substituent, but is preferably unsubstituted.

Examples of the halogen atom represented by Re¹ include a fluorine atom, a chlorine atom, a bromine atom, and an iodine atom.

Le¹ represents a single bond or a divalent linking group, and a divalent linking group is preferable. Examples of the divalent linking group include an alkylene group, an arylene group, —O—, —NR′— (R′ represents a hydrogen atom, an alkyl group which may have a substituent, or an aryl group which may have a substituent), —SO₂—, —CO—, —O—, —OCO—, —COO—, —S—, —SO—, and a group composed of a combination of these, and an alkylene group is preferable.

The number of carbon atoms in the alkylene group is preferably 1 to 30 and more preferably 1 to 12. The alkylene group is preferably linear or branched, and more preferably branched.

The weight-average molecular weight (Mw) of the epoxy resin is preferably 100 to 10000, more preferably 500 to 5000, and still more preferably 1000 to 3000. In addition, the epoxy equivalent (=the molecular weight of the epoxy resin/the number of epoxy groups included in the epoxy resin) of the epoxy resin is preferably 50 to 800 g/eq, more preferably 80 to 500 g/eq, and still more preferably 100 to 300 g/eq. In a case where the epoxy equivalent of the epoxy resin is within the above-described range, both the heat resistance and the mechanical strength of the cured film can be achieved at a high level.

Specific examples of the compound represented by Formula (EP-1) include a compound obtained as a main component by a reaction between a phenol resin, which is obtained by a reaction of 1-[4-(1-hydroxy-1-methyl-ethyl)-phenyl]ethanone and phenols (unsubstituted phenols or phenols having, as a substituent, an alkyl group having 1 to 12 carbon atoms, an alkoxy group having 1 to 12 carbon atoms, or a halogen atom), and epihalohydrin (at least one selected from epichlorohydrin or epibromohydrin). Examples of a commercially available product of the epoxy resin include VG-3101M80 (manufactured by Printec Co.) NC-6000 and NC-6300 (all of which are manufactured by Nippon Kayaku Co., Ltd.), and DENACOL EX-611 (manufactured by Nagase ChemteX Corporation).

[Bismaleimide Resin]

Examples of the bismaleimide resin include a compound represented by Formula (BM-1).

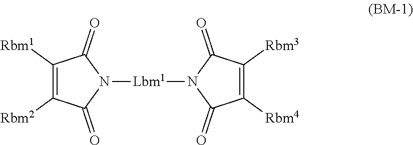

In Formula (BM-1), Rbm¹ to Rbm⁴ each independently represent a hydrogen atom or a substituent, and Lbm¹ represents a divalent linking group.

Examples of the substituent represented by Rbm¹ to Rbm⁴ include a halogen atom, an alkyl group, an aryl group, and a heterocyclic group.

Examples of the divalent linking group represented by Lbm¹ include an alkylene group, an arylene group, —O—, —NR′— (R′ represents a hydrogen atom, an alkyl group which may have a substituent, or an aryl group which may have a substituent), —SO₂—, —CO—, —O—, —OCO—, —COO—, —S—, —SO—, and a group composed of a combination of these.

Specific examples of the bismaleimide resin include compounds having the following structures.

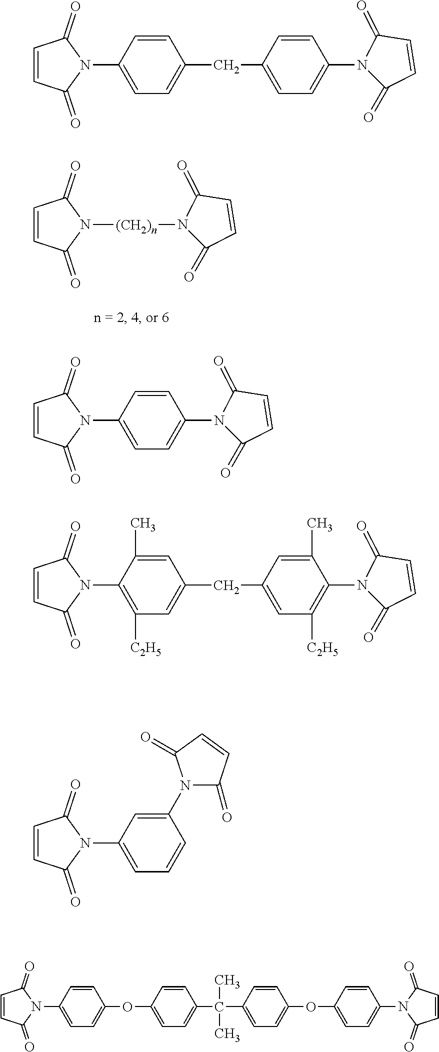

Examples of a commercially available product of the bismaleimide resin include HR3030, 3032, and 3070 (all of which are manufactured by Printec Co.), BMI-1000 and BMI-2000 (both of which are manufactured by Daiwa Kasei Industry Co., Ltd.), and Sanfel BM-G (manufactured by SANSHIN CHEMICAL INDUSTRY CO., LTD.).

[Silicone Resin]

Examples of the silicone resin include a resin having a repeating unit including a siloxane bond. In the silicone resin, the repeating unit including a siloxane bond may be included in the main chain or the side chain. Examples of the silicone resin include an epoxy-modified silicone resin, a polyester-modified silicone resin, an alkyd-modified silicone resin, a urethane-modified silicone resin, and an acrylic-modified silicone resin, and these can be preferably used. Among these, from the reason that heat resistance of the cured film can be more easily improved, an epoxy-modified silicone resin or a polyester-modified silicone resin is preferable.

The weight-average molecular weight (Mw) of the silicone resin is preferably 500 to 1000000, more preferably 1000 to 100000, and still more preferably 2000 to 20000.

Examples of one aspect of the silicone resin include a reactant of a compound having a hydroxy group and an epoxy group with a silsesquioxane compound containing an epoxy group and an alkoxy group.

The silicone resin of this embodiment preferably has an epoxy group. In addition, the epoxy equivalent of the silicone resin of this embodiment is preferably 150 to 500 g/eq. In addition, in the silicone resin of this embodiment, the ratio of the number of moles of epoxy groups derived from the compound having a hydroxy group and an epoxy group and the number of moles of epoxy groups derived from the silsesquioxane compound containing an epoxy group and an alkoxy group ((number of moles of epoxy groups derived from the compound having a hydroxy group and an epoxy group)/(number of moles of epoxy groups derived from the silsesquioxane compound containing an epoxy group and an alkoxy group)) is preferably 0.1 to 3.

In addition, the silicone resin of this embodiment also preferably has an alkoxy group. The amount of the alkoxy group included in the silicone resin is preferably 150 to 3000 g/eq.

Examples of the above-described compound having a hydroxy group and an epoxy group include bisphenol-type epoxy resins such as a bisphenol A-type epoxy resin, a bisphenol F-type epoxy resin, and a bisphenol S-type epoxy resin, a hydrogenated bisphenol type epoxy resin with nuclear hydrogenated benzene ring of epoxy resin, a phenolic novolac-type epoxy resin, a cresol novolac-type epoxy resin, a biphenol-type epoxy resin, and a naphthalene-type epoxy resin.

The average number of hydroxy groups included in the compound having a hydroxy group and an epoxy group is preferably 0.3 to 5.

Examples of the above-described silsesquioxane compound containing an epoxy group and an alkoxy group include a compound obtained by hydrolyzing and condensing a compound represented by Formula (Si-1).

Rs¹Si(ORs²)₃ (Si-1)

(in the formula, Rs¹ represents a hydrocarbon group having 3 to 8 carbon atoms, which has an epoxy group, and Rs² represents a hydrogen atom or a hydrocarbon group having 1 to 4 carbon atoms)

Specific examples of the compound represented by Formula (Si-1) include glycydoxypropyltrialkoxysilanes such as 3-glycidoxypropyltrimethoxysilane, 3-glycidoxypropyltriethoxysilane, and 3-glycidoxypropyltripropoxysilane; and (epoxycyclohexyl)ethyltrialkoxysilanes such as 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane.

In addition to the above-described compound represented by Formula (Si-1), metal alkoxides which do not contain an epoxy group, such as trialkylalkoxysilanes such as trimethylmethoxysilane, trimethylethoxysilane, triethylmethoxysilane, triethylethoxysilane, triphenylmethoxysilane, and triphenylethoxysilane; dialkyldialkoxysilanes such as dimethyldimethoxysilane, dimethyldiethoxysilane, diethyldimethoxysilane, diethyldiethoxysilane, diphenyldimethoxysilane, diphenyldiethoxysilane, methylphenyldimethoxysilane, methylphenyldiethoxysilane, and 3-mercaptopropylmethyldimethoxysilane; alkyltrialkoxysilanes such as methyltrimethoxysilane, methyltriethoxysilane, ethyltrimethoxysilane, ethyltriethoxysilane, phenyltrimethoxysilane, and phenyltriethoxysilane; tetraalkoxysilanes such as tetramethoxysilane, tetraethoxysilane, tetrapropoxysilane, and tetrabutoxysilane; tetraalkoxytitaniums such as tetramethoxytitanium, tetraethoxytitanium, tetrapropoxytitanium, and tetrabutoxytitanium; and tetraalkoxyzirconiums such as tetraethoxyzirconium, tetrapropoxyzirconium, and tetrabutoxyzirconium, may be further used in combination.

(Total of the number of moles of alkoxy groups included in the compound represented by Formula (Si-1) and the number of moles of alkoxy groups included in the metal alkoxides)/(total of the number of moles of the compound represented by Formula (Si-1) and the number of moles of the metal alkoxides) is preferably 2.5 to 3.5 and more preferably 2.7 to 3.2.

By hydrolyzing and condensing the compound represented by Formula (Si-1) or a mixture of the compound represented by Formula (Si-1) and the above-described metal alkoxides, the silsesquioxane compound containing an epoxy group and an alkoxy group is obtained. By the hydrolysis reaction, the alkoxy group included in the compound represented by Formula (Si-1) and the above-described metal alkoxides forms a silanol group, and an alcohol is by-produced. As an amount of water required for the hydrolysis reaction, (number of moles of water used for the hydrolysis reaction)/(total number of moles of each alkoxy group included in the compound represented by Formula (Si-1) and the metal alkoxides) is preferably 0.2 to 1 and more preferably 0.3 to 0.7.

In reacting the compound having a hydroxy group and an epoxy group with the silsesquioxane compound containing an epoxy group and an alkoxy group to obtain a silicone resin which is a reactant thereof, the ratio of use of the compound having a hydroxy group and an epoxy group and the silsesquioxane compound containing an epoxy group and an alkoxy group is preferably 20 to 800 parts by mass of the compound having a hydroxy group and an epoxy group, and more preferably 50 to 500 parts by mass of the compound having a hydroxy group and an epoxy group with respect to 100 parts by mass of the silsesquioxane compound containing an epoxy group and an alkoxy group.

Specific examples of the silicone resin include compounds having the following structures.

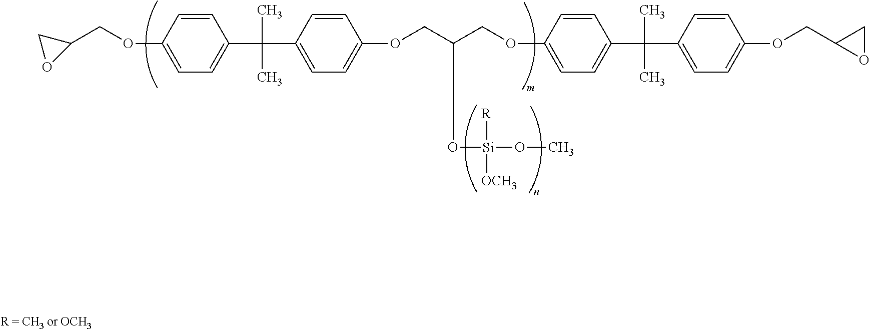

Examples of a commercially available product of the silicone resin include KR-5230, KR-5234, and KR-5235 (all of which are manufactured by Shin-Etsu Chemical Co., Ltd.), and COMPOCERAN E103A, E103D, and E203 (all of which are manufactured by Arakawa Chemical Industries, Ltd.).

(Other Resin)

The resin composition according to the embodiment of the present invention can further contain a resin other than the above-described resin A. In a case where the other resin is further contained, it is also possible to impart appropriate flexibility to the film obtained by using the resin composition. Therefore, in a case where an inorganic film is formed on a surface of the film obtained using the resin composition according to the embodiment of the present invention, it is also possible to effectively suppress the occurrence of cracks in the inorganic film even in a case where this laminate is exposed to a high temperature. In addition, in a case of resolving by photolithography using the resin composition according to the embodiment of the present invention, since the resin composition according to the embodiment of the present invention contains a resin having an alkali developability, other than the above-described resin A, it is also possible to improve resolution.

The weight-average molecular weight (Mw) of the other resin is preferably 3000 to 2000000. The upper limit is more preferably 1000000 or less and still more preferably 500000 or less. The lower limit is more preferably 4000 or more and still more preferably 5000 or more.

Examples of the other resin include a (meth)acrylic resin, a polyimine resin, a polyether resin, a polyolefin resin, a cyclic olefin resin, a polyester resin, and a styrene resin, and a (meth)acrylic resin or a polyimine resin is preferable and a (meth)acrylic resin is more preferable. In addition, as the other resin, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

In addition, as the other resin, it is preferable to use a resin having an acid group. According to this aspect, developability of the resin composition can be further improved. Examples of the acid group include a phenolic hydroxy group, a carboxy group, a sulfo group, a phosphoric acid group, and a phosphate group, and a carboxy group is preferable. The resin having an acid group can be used, for example, as an alkali-soluble resin.

The resin having an acid group preferably includes a repeating unit having an acid group in the side chain, and more preferably includes 1 to 70 mol % of repeating units having an acid group in the side chain with respect to the total repeating units of the resin. The upper limit of the content of the repeating unit having an acid group in the side chain is preferably 50 mol % or less and more preferably 40 mol % or less. The lower limit of the content of the repeating unit having an acid group in the side chain is preferably 2 mol % or more and more preferably 5 mol % or more.

The acid value of the resin having an acid group is preferably 200 mgKOH/g or less, more preferably 150 mgKOH/g or less, still more preferably 120 mgKOH/g or less, and particularly preferably 100 mgKOH/g or less. In addition, the acid value of the resin having an acid group is preferably 5 mgKOH/g or more, more preferably 10 mgKOH/g or more, and still more preferably 20 mgKOH/g or more.

The resin having an acid group also preferably has an ethylenically unsaturated bond-containing group. Examples of the ethylenically unsaturated bond-containing group include a vinyl group, an allyl group, and a (meth)acryloyl group, and an allyl group or a (meth)acryloyl group is preferable and a (meth)acryloyl group is more preferable.

The resin having an ethylenically unsaturated bond-containing group preferably includes a repeating unit having an ethylenically unsaturated bond-containing group in the side chain, and more preferably includes 5 to 80 mol % of the repeating unit having an ethylenically unsaturated bond-containing group in the side chain with respect to the total repeating units of the resin. The upper limit of the content of the repeating unit having an ethylenically unsaturated bond-containing group in the side chain is preferably 60 mol % or less and more preferably 40 mol % or less. The lower limit of the content of the repeating unit having an ethylenically unsaturated bond-containing group in the side chain is preferably 10 mol % or more and more preferably 15 mol % or more.

It is also preferable that the other resin include a repeating unit derived from a monomer component including a compound represented by Formula (ED1) and/or a compound represented by Formula (ED2) (hereinafter, these compounds may be referred to as an “ether dimer”).

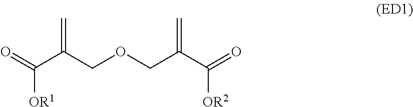

In Formula (ED1), R¹ and R² each independently represent a hydrogen atom or a hydrocarbon group having 1 to 25 carbon atoms, which may have a substituent.

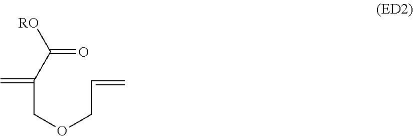

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the other resin includes a repeating unit derived from a compound represented by Formula (X).

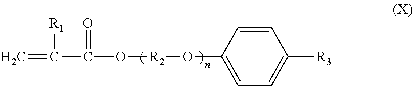

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

Examples of the resin having an acid group include a resin having the following structures. In the following structural formulae, Me represents a methyl group.

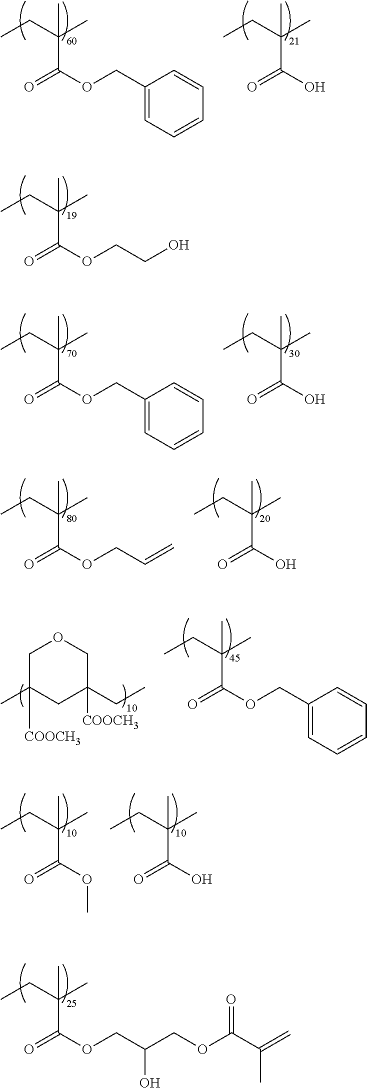

(Dispersant)

The resin composition according to the embodiment of the present invention can also include a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group included in the acidic dispersant (acidic resin) is preferably a carboxy group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group.

It is also preferable that the resin used as a dispersant is a graft resin. Examples of the graft resin include resins described in paragraph Nos. 0025 to 0094 of JP2012-255128A, the contents of which are incorporated herein by reference.

It is also preferable that the resin used as a dispersant is a polyimine-based dispersant (polyimine resin) including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. Examples of the polyimine-based dispersant include resins described in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

In addition, the resins described in the section of resin A above and the resins described in the section of other resin above can also be used as the dispersant.

A commercially available product is also available as the dispersant, and specific examples thereof include DISPERBYK series (for example, DISPERBYK-111, 161, and the like) manufactured by BYK Chemie, and Solsperse series (for example, Solsperse 36000) manufactured by Lubrizol Corporation. The dispersing agents described in paragraph Nos. 0041 to 0130 of JP2014-130338A can also be used, the contents of which are incorporated herein by reference.

The resin described as a dispersant can be used for an application other than the dispersant. For example, the resin can also be used as a binder.

The content of the resin in the total solid content of the resin composition is preferably 10 to 95 mass %. The lower limit is more preferably 20 mass % or more and still more preferably 30 mass % or more. The upper limit is more preferably 90 mass % or less and still more preferably 85 mass % or less.

In addition, the content of the above-described resin A in the total solid content of the resin composition is preferably 5 to 95 mass %. The lower limit is preferably 10 mass % or more and more preferably 20 mass % or more. The upper limit is preferably 90 mass % or less and more preferably 85 mass % or less.

In the components in which the coloring material is excepted from a total solid content of the resin composition, the resin A is included preferably in an amount of 20 mass % or more, more preferably in an amount of 30 mass % or more, and still more preferably in an amount of 40 mass % or more. The upper limit may be 100 mass %, 90 mass % or less, or 85 mass % or less. In a case where the content of the resin A is within the above-described range, it is easy to form a film having excellent heat resistance, and it is easy to suppress film contraction and discoloration after heating. Further, in a case where an inorganic film is formed on a surface of the film obtained using the resin composition according to the embodiment of the present invention, it is also possible to suppress the occurrence of cracks in the inorganic film even in a case where this laminate is exposed to a high temperature.

In addition, the total content of the coloring material and the above-described resin A in the total solid content of the resin composition is preferably 25 to 100 mass %. The lower limit is more preferably 30 mass % or more and still more preferably 40 mass % or more. The upper limit is more preferably 90 mass % or less and still more preferably 80 mass % or less.

In addition, the ratio of the coloring material and the above-described resin A in the total solid content of the resin composition is preferably 3 to 1500 parts by mass of the resin A with respect to 100 parts by mass of the coloring material. The lower limit is preferably 5 parts by mass or more and more preferably 10 parts by mass or more. The upper limit is preferably 1000 parts by mass or less and more preferably 500 parts by mass or less.

In the resin composition, the content of the other resin described above is preferably 230 parts by mass or less, more preferably 200 parts by mass or less, and still more preferably 150 parts by mass or less with respect to 100 parts by mass of the above-described resin A. The lower limit may be 0 part by mass, 5 parts by mass or more, or 10 parts by mass or more. In addition, it is also preferable that the resin composition does not substantially include the above-described other resin. According to this aspect, it is easy to form a film having more excellent heat resistance. The case where the resin composition does not substantially include the other resin means that the content of the other resin in the total solid content of the resin composition is 0.1 mass % or less, preferably 0.05 mass % or less, and more preferably 0 mass %.

<<Solvent>>

The resin composition according to the embodiment of the present invention contains a solvent. As the solvent, an organic solvent is preferable. Basically, the organic solvent is not particularly limited as long as it satisfies the solubility of the respective components and the application properties of the resin composition. Examples of the organic solvent include an ester solvent, a ketone solvent, an alcohol solvent, an amide solvent, an ether solvent, and a hydrocarbon solvent. The details of the organic solvent can be found in paragraph No. 0223 of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, 3-butoxy-N,N-dimethylpropanamide, γ-butyrolactone, and N-methyl-2-pyrrolidone. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015). Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

The content of the organic solvent in the resin composition is preferably 10 to 95 mass %, more preferably 20 to 90 mass %, and still more preferably 30 to 90 mass %.

<<Pigment Derivative>>

The resin composition according to the embodiment of the present invention can contain a pigment derivative. Examples of the pigment derivative include a compound having a structure in which a part of a chromophore is substituted with an acid group, a basic group, or a phthalimidomethyl group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. As the acid group included in the pigment derivative, a sulfo group or a carboxy group is preferable and a sulfo group is more preferable. As the basic group included in the pigment derivative, an amino group is preferable and a tertiary amino group is more preferable.

As the pigment derivative, a pigment derivative having excellent visible transparency (hereinafter, also referred to as a transparent pigment derivative) can be used. The maximum value (εmax) of the molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

The content of the pigment derivative is preferably 1 to 30 parts by mass and still more preferably 3 to 20 parts by mass with respect to 100 parts by mass of the pigment. The pigment derivative may be used singly or in combination of two or more kinds thereof

<<Polymerizable Compound>>

The resin composition according to the embodiment of the present invention can contain a polymerizable compound. The polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bond-containing groups, more preferably a compound including 3 to 15 ethylenically unsaturated bond-containing groups, and still more preferably a compound having 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in a non-exposed portion is easily removed during development and the generation of the development residue can be suppressed. Examples of the acid group include a carboxy group, a sulfo group, and a phosphoric acid group, and a carboxy group is preferable. Examples of a commercially available product of the polymerizable compound having an acid group include ARONIX M-305, M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd., which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, AI-600, and LINC-202UA (manufactured by KYOEISHA CHEMICAL Co., Ltd.) can also be used.

In a case of containing a polymerizable compound, the content of the polymerizable compound in the total solid content of the resin composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof

<<Photopolymerization Initiator>>

The resin composition according to the embodiment of the present invention can contain a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton, a compound having an oxadiazole skeleton, a compound having an imidazole skeleton, and the like), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a biimidazole compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from a biimidazole compound, an oxime compound, an α-hydroxyketone compound, an α-aminoketone compound, or an acylphosphine compound is more preferable, and an oxime compound is still more preferable. Examples of the photopolymerization initiator include compounds described in paragraphs 0065 to 0111 of JP2014-130173A, and JP6301489B, the contents of which are incorporated herein by reference.

Examples of the biimidazole compound include 2,2-bis(2-chlorophenyl)-4,4′,5,5 ‘-tetraphenylbiimidazole, 2,2’-bis(o-chlorophenyl)-4,4′,5,5-tetrakis(3,4,5-trimethoxyphenyl)-1,2′-biimidazole, 2,2′-bis(2,3-dichlorophenyl)-4,4′,5,5 ‘-tetraphenylbiimidazole, and 2,2’-bis (o-chlorophenyl)-4,4,5,5′-tetraphenyl-1,2′-biimidazole. Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins RV), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A.

In addition, as the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

An oxime compound having a nitro group can be used as the photopolymerization initiator. It is preferable that the oxime compound having a nitro group is a dimer. Specific examples of the oxime compound having a nitro group include a compound described in paragraph Nos. 0031 to 0047 of JP2013-114249A and paragraph Nos. 0008 to 0012 and 0070 to 0079 of JP2014-137466A, a compound described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

Specific examples of the oxime compound are shown below, but the present invention is not limited thereto.

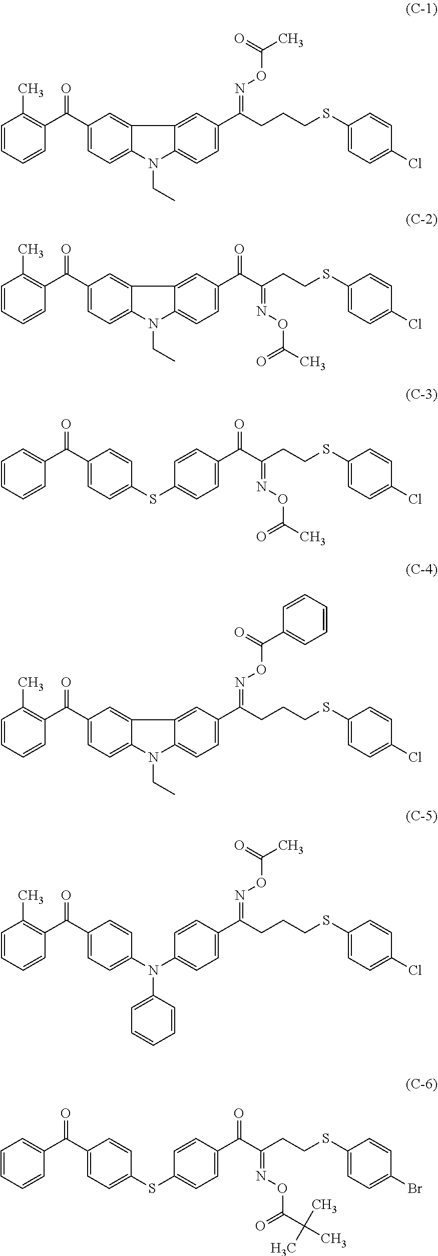

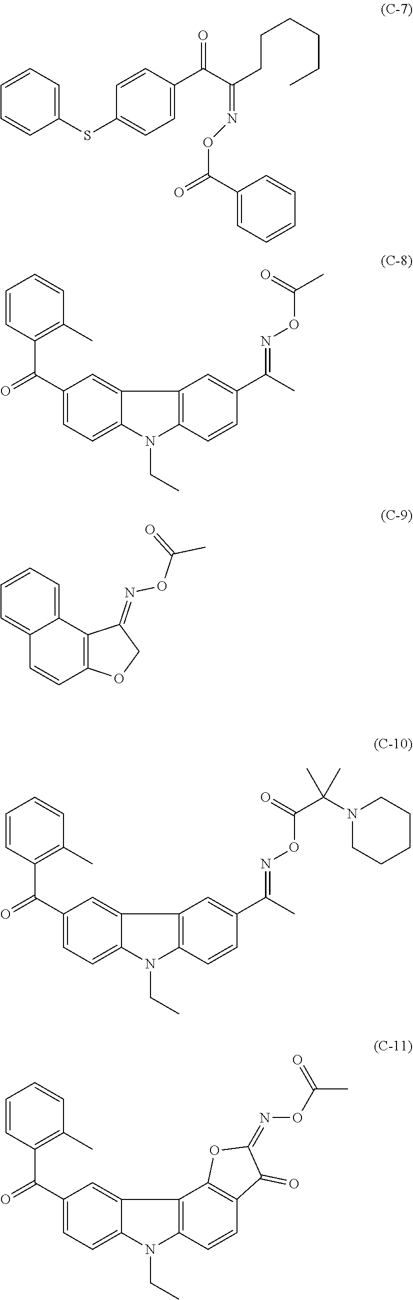

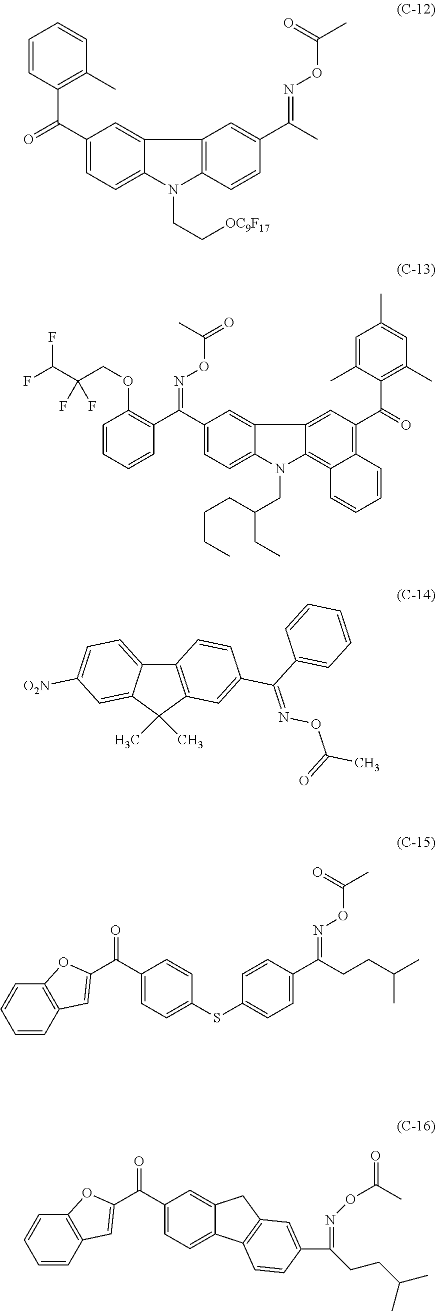

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate at a concentration of 0.01 g/L.

As the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the resin composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime compound described in JP6469669B.

In a case of containing a photopolymerization initiator, the content of the photopolymerization initiator in the total solid content of the resin composition is preferably 0.1 to 30 mass %. The lower limit is preferably 0.5 mass % or more and more preferably 1 mass % or more. The upper limit is preferably 20 mass % or less and more preferably 15 mass % or less. The photopolymerization initiator may be used singly or in combination of two or more kinds thereof

<<Silane Coupling Agent>>

The resin composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureide group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the resin composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof

<<Curing Accelerator>>

For the purpose of promoting the reaction of the resin and the polymerizable compound and lowering the curing temperature, the resin composition according to the embodiment of the present invention can further contain a curing accelerator. As the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used.

In a case where the resin composition according to the embodiment of the present invention contains a curing accelerator, the content of the curing accelerator is preferably 0.3 to 8.9 mass % and more preferably 0.8 to 6.4 mass % with respect to the total solid content of the resin composition.

<<Polymerization Inhibitor>>

The resin composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the resin composition is preferably 0.0001 to 5 mass %.

<<Surfactant>>

The resin composition according to the embodiment of the present invention can contain a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the resin composition, liquid characteristics (particularly, fluidity) are further improved, and liquid saving properties can be further improved. In addition, it is possible to form a film with a small thickness unevenness.

The fluorine content in the fluorine-based surfactant is preferably 3 to 40 mass %, more preferably 5 to 30 mass %, and particularly preferably 7 to 25 mass %. The fluorine-based surfactant in which the fluorine content is within the above-described range is effective in terms of the evenness of the thickness of the coating film or liquid saving properties and the solubility of the surfactant in the resin composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used. With regard to such a fluorine-based surfactant, reference can be made to the description in JP2016-216602A, the contents of which are incorporated herein by reference.

As the fluorine-based surfactant, a block polymer can also be used. Examples thereof include the compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. The following compounds are also exemplified as the fluorine-based surfactant used in the present invention.

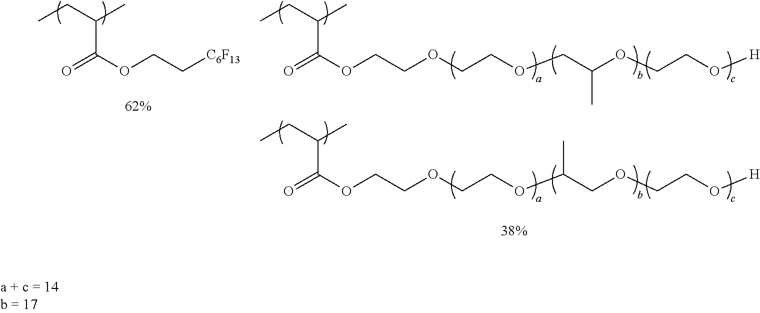

The weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include the compounds described in paragraph Nos. 0050 to 0090 and paragraph Nos. 0289 to 0295 of JP2010-164965A, and for example, MEGAFACE RS-101, RS-102, RS-718K, and RS-72-K manufactured by DIC Corporation. As the fluorine-based surfactant, the compounds described in paragraph Nos. 0015 to 0158 of JP2015-117327A can also be used.

The content of the surfactant in the total solid content of the resin composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<<Ultraviolet Absorber>>

The resin composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. The content of the ultraviolet absorber in the total solid content of the resin composition is preferably 0.01 to 10 mass % and more preferably 0.01 to 5 mass %. The ultraviolet absorber may be used singly or in combination of two or more kinds thereof. In a case where two or more kinds thereof are used, the total content thereof is preferably within the above-described range.

<<Antioxidant>>

The resin composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. The content of the antioxidant in the total solid content of the resin composition is preferably 0.01 to 20 mass % and more preferably 0.3 to 15 mass %. The antioxidant may be used singly or in combination of two or more kinds thereof. In a case where two or more kinds thereof are used, the total content thereof is preferably within the above-described range.

<<Other Components>>

Optionally, the resin composition according to the embodiment of the present invention may further contain a sensitizer, a filler, a thermal curing accelerator, a plasticizer, and other auxiliary agents (for example, conductive particles, an anti-foaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph Nos. 0183 and later of JP2012-003225A (corresponding to paragraph No. 0237 of US2013/0034812A) and paragraph Nos. 0101 to 0104 and 0107 to 0109 of JP2008-250074A, the content of which is incorporated herein by reference. In addition, optionally, the resin composition may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product thereof include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the resin composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The resin composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to “0052 of JP2017-129774A, the compounds described in paragraph Nos. 0031 to 0034, 0058, and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the resin composition according to the embodiment of the present invention, the content of liberated metal which is not bonded to or coordinated with a pigment or the like is preferably 100 ppm or less, more preferably 50 ppm or less, and still more preferably 10 ppm or less, it is particularly preferable to not contain the liberated metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the resin composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the resin composition include washing with ion exchange water, filtration, ultrafiltration, and purification with an ion exchange resin.

It is also preferable that the resin composition according to the embodiment of the present invention does not substantially include terephthalic acid ester. Here, the “does not substantially include” means that the content of terephthalic acid ester is 1000 mass ppb or less in the total amount of the resin composition, and it is more preferable to be 100 mass ppb or less and particularly preferable to be 0.

<Storage Container>

A storage container of the resin composition according to the embodiment of the present invention is not particularly limited, and a known storage container can be used. In addition, as the storage container, in order to suppress infiltration of impurities into the raw materials or the resin composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351A. In addition, for the purpose of preventing metal elution from the container inner wall, improving storage stability of the resin composition, and suppressing the alteration of components, it is also preferable that the container inner wall is formed of glass, stainless steel, or the like.

<Method for Preparing Resin Composition>

The resin composition according to the embodiment of the present invention can be prepared by mixing the above-described components with each other. During the preparation of the resin composition, all the components may be dissolved and/or dispersed in an organic solvent at the same time to prepare the resin composition. Optionally, two or more solutions or dispersion liquids in which the respective components are appropriately blended may be prepared, and the solutions or dispersion liquids may be mixed with each other during use (during application) to prepare the resin composition.

In addition, in the preparation of the resin composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the resin composition, it is preferable that the resin composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha., Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and then the filtering using the second filter may be performed on a mixture of the dispersion liquid and other components.

<Film>

The film according to the embodiment of the present invention is a film obtained from the above-described resin composition according to the embodiment of the present invention. The film according to the embodiment of the present invention can be used for a color filter, a near-infrared transmitting filter, a near-infrared cut filter, a black matrix, a light-shielding film, and the like. For example, the film according to the embodiment of the present invention can be preferably used as a colored layer of a color filter.

The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In a case where the film according to the embodiment of the present invention is heat-treated at 300° C. for 5 hours in a nitrogen atmosphere, a rate of change ΔA in an absorbance of the film after performing the heating treatment, which is represented by Expression (1), is preferably 50% or less, more preferably 45% or less, still more preferably 40% or less, and particularly preferably 35% or less.

ΔA=|100−(A2/A1)×100| (1)

ΔA is the rate of change in the absorbance of the film after the heating treatment;

A1 is the maximum value of the absorbance of the film before the heating treatment in a wavelength range of 400 to 1100 nm; and

A2 is the absorbance of the film after the heating treatment, and is the absorbance at the wavelength showing the maximum value of the film before the heating treatment in a wavelength range of 400 to 1100 nm.

In addition, in the film according to the embodiment of the present invention, an absolute value of a difference between a wavelength λ1 showing the maximum value of the absorbance of the film in a wavelength range of 400 to 1100 nm and a wavelength λ2 showing the maximum value of the absorbance of the film after the heating treatment at 300° C. for 5 hours in a nitrogen atmosphere is preferably 50 nm or less, more preferably 45 nm or less, and still more preferably 40 nm or less.

In addition, in the film according to the embodiment of the present invention, a maximum value of the rate of change in an absorbance of the film after the heating treatment at 300° C. for 5 hours in a nitrogen atmosphere in a wavelength range of 400 to 1100 nm is preferably 30% or less, more preferably 27% or less, and still more preferably 25% or less. The rate of change in the absorbance is a value calculated from Expression (2).

ΔA_{λ}=|100−(A2_{λ}/A1_{λ})×100| (2)

ΔA_{λ} is the rate of change in the absorbance of the film after the heating treatment at a wavelength λ;

A1_{λ} is the absorbance of the film before the heating treatment at the wavelength λ; and

A2_{λ} is the absorbance of the film after the heating treatment at the wavelength λ.

<Method for Manufacturing Film>

The film according to the embodiment of the present invention can be manufactured through a step of applying the resin composition according to the embodiment of the present invention on a support. The method for manufacturing the film according to the embodiment of the present invention preferably further includes a step of forming a pattern (pixel). Examples of a method for forming the pattern (pixel) include a photolithography method and a dry etching method, and a photolithography method is preferable.

(Photolithography Method)

First, a case of forming the pattern by a photolithography method to manufacture a film will be described. Pattern formation by the photolithography method preferably includes a step of forming a resin composition layer on a support using the resin composition according to the embodiment of the present invention, a step of exposing the resin composition layer in a patterned manner, and a step of removing a non-exposed portion of the resin composition layer by development to form a pattern (pixel). A step (pre-baking step) of baking the resin composition layer and a step (post-baking step) of baking the developed pattern (pixel) may be provided, optionally.

In the step of forming a resin composition layer, the resin composition layer is formed on a support using the resin composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the resin composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. The application method using an ink jet method is not particularly limited, and examples thereof include a method (in particular, pp. 115 to 133) described in “Extension of Use of Ink Jet—Infinite Possibilities in Patent-” (published on February, 2005, S.B. Research Co., Ltd.) and methods described in JP2003-262716A, JP2003-185831A, JP2003-261827A, JP2012-126830A, and JP2006-169325A. In addition, as the method of applying the resin composition, methods described in WO2017/030174A and WO2017/018419A can also be used, the contents of which are incorporated herein by reference.

The resin composition layer formed on the support may be dried (pre-baked). In a case of producing a film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

Next, the resin composition layer is exposed in a patterned manner (exposing step). For example, the resin composition layer can be exposed in a patterned manner using a stepper exposure device or a scanner exposure device through a mask having a predetermined mask pattern. As a result, an exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m2 to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the resin composition layer is removed by development to form a pattern (pixel). The non-exposed portion of the resin composition layer can be removed by development using a developer. Thus, the resin composition layer of the non-exposed portion in the exposing step is eluted into the developer, and as a result, only a photocured portion remains. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

Examples of the developer include an organic solvent and an alkali developer, and an alkali developer is preferably used. As the alkali developer, an alkaline solution (alkali developer) in which an alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium hydrogen carbonate, sodium silicate, and sodium metasilicate. In consideration of environmental aspects and safety aspects, the alkaline agent is preferably a compound having a high molecular weight. The concentration of the alkaline agent in the alkaline solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the resin composition layer after development while rotating the support on which the resin composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

(Dry Etching Method)

Pattern formation by a dry etching method preferably includes a step of forming a resin composition layer on a support using the resin composition according to the embodiment of the present invention and curing the entire resin composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heat treatment after exposure and a heat treatment after development (post-baking treatment) are performed. The details of the pattern formation by the dry etching method can be found in paragraph Nos. 0010 to 0067 of JP2013-064993A, the content of which is incorporated herein by reference.

<Color Filter>

The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the film according to the embodiment of the present invention can be appropriately adjusted depending on the purposes. The thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured using an ultrahigh resistance meter 5410 (manufactured by Advantest Corporation).

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition for forming a protective layer, which is dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition for forming a protective layer, as a method for applying the resin composition for forming a protective layer, a known method such as a spin coating method, a casting method, a screen printing method, and an ink jet method can be used. As the organic solvent included in the resin composition for forming a protective layer, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1 to 70 mass % and still more preferably 1 to 60 mass % with respect to the total mass of the protective layer.

In addition, as the protective layer, the protective layers described in paragraph Nos. 0073 to 0092 of JP2017-151176A can also be used.

The color filter may have a structure in which each colored pixel is embedded in a space partitioned in, for example, a lattice form by a partition wall.

<Solid-State Imaging Element>

A solid-state imaging element according to the embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. In this case, it is preferable that the partition wall has a lower refractive index than each colored pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle-mounted camera or a monitoring camera, in addition to a digital camera or electronic equipment (mobile phones or the like) having an imaging function.

<Image Display Device>

The image display device according to the embodiment of the present invention has the film according to the embodiment of the present invention. Examples of the image display device include a liquid crystal display device or an organic electroluminescence display device. The definitions of image display devices or the details of the respective image display devices are described in, for example, “Electronic Display Device (edited by Akio Sasaki, Kogyo Chosakai Publishing Co., Ltd., published in 1990)”, “Display Device (edited by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples. Unless specified otherwise, “part(s)” and “%” represent “part(s) by mass” and “mass %”.

<Measurement of Weight-Average Molecular Weight (Mw) of Sample>

The weight-average molecular weight (Mw) of a sample was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

<Measurement of Acid Value of Sample>

The acid value of the sample represents a mass of potassium hydroxide required to neutralize acidic components per 1 g of solid content of the sample. The acid value of the sample was measured as follows. That is, a measurement sample was dissolved in a mixed solvent of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the sample (expressed in terms of solid contents)

(Production of Dispersion Liquid)

A mixed solution obtained by mixing raw materials listed in the table below was mixed and dispersed for 3 hours by a beads mill (zirconia beads: 0.3 mm diameter), and then subjected to a dispersion treatment under a pressure of 2,000 kg/cm³ at a flow rate of 500 g/min using a high-pressure disperser equipped with a pressure-reducing system NANO-3000-10 (manufactured by Nippon BEE Chemical Co., Ltd.). The dispersion treatment was repeated 10 times to obtain a dispersion liquid.

TABLE 1

| | Coloring material (pigment) | | | | | | | | Pigment derivative | | | | | | | | | | | |
|---|---|---|---|---|---|---|---|---|---|---|---|---|---|---|---|---|---|---|---|---|
| | PR- | PR- | PB- | PB- | PB- | PY- | Pc- | IR pig- | Deriv- | Deriv- | Resin (dispersant) | | | | | | | Solvent | | |
| | 264 | 254 | 15:4 | 15:6 | 16 | 139 | Al | ment | ative 1 | ative 2 | B-1 | B-2 | B-3 | B-4 | B-5 | B-14 | B-15 | S-1 | S-2 | S-3 |
| Dispersion | 10.4 | | | | | | | | 2.6 | | 4.5 | | | | | | | 82.5 | | |
| liquid R1 | | | | | | | | | | | | | | | | | | | | |
| Dispersion | | 11.6 | | | | | | | 1.4 | | 4.5 | | | | | | | 82.5 | | |
| liquid R2 | | | | | | | | | | | | | | | | | | | | |
| Dispersion | | | 13.2 | | | | | | | | | | 1.5 | 4.6 | 0.5 | | | 80.2 | | |
| liquid B1 | | | | | | | | | | | | | | | | | | | | |
| Dispersion | | | | 10.8 | | | | | | | | 1.5 | 1.5 | | | | | 67.7 | 17.0 | 1.5 |
| liquid B2 | | | | | | | | | | | | | | | | | | | | |
| Dispersion | | | | | 13.0 | | | | | | | | 6.5 | | | | | 75.1 | 5.4 | |
| liquid B3 | | | | | | | | | | | | | | | | | | | | |
| Dispersion | | | | | | | 11.0 | | | | | | 7.4 | | | | | 75.7 | 5.9 | |
| liquid B4 | | | | | | | | | | | | | | | | | | | | |
| Dispersion | | 7.0 | | 7.2 | | 3.9 | | | | | | | | | | 8.4 | | 73.6 | | |
| liquid BK | | | | | | | | | | | | | | | | | | | | |
| Dispersion | | | | | | | | 7.3 | | 1.3 | | | | | | | 4.7 | 86.7 | | |
| liquid IR | | | | | | | | | | | | | | | | | | | | |

The unit of numerical values shown in the above table is part by mass. Among the raw materials shown in the above table, details of the raw materials shown by abbreviations are as follows.

(Pigment)

PR254: C. I. Pigment Red 254 (red pigment, diketopyrrolopyrrole pigment)

PR264: C. I. Pigment Red 264 (red pigment, diketopyrrolopyrrole pigment)

PB15:4: C. I. Pigment Blue 15:4 (blue pigment, phthalocyanine pigment)

PB15:6: C. I. Pigment Blue 15:6 (blue pigment, phthalocyanine pigment)

PB16: C. I. Pigment Blue 16 (blue pigment, phthalocyanine pigment)

PY139: C. I. Pigment Yellow 139 (yellow pigment, isoindoline pigment)

PcAl: aluminum phthalocyanine (blue pigment, compound having the following structure)

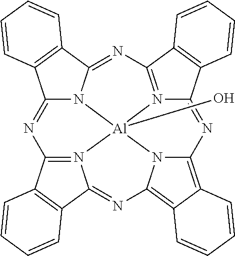

IR pigment: compound having the following structure (near-infrared absorbing pigment, in the following structural formula, Me represents a methyl group and Ph represents a phenyl group)

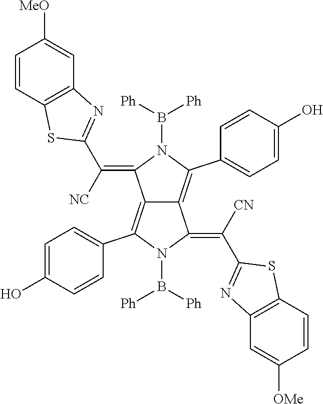 [SMILES: COc1ccc2sc(/C(C#N)=c3/c4c(-c5ccc(O)cc5)n(B(c5ccccc5)c5ccccc5)/c(=C(/C#N)c5nc6cc(OC)ccc6s5)c4c(-c4ccc(O)cc4)n3B(c3ccccc3)c3ccccc3)nc2c1]

All of C. I. Pigment Red 254, C. I. Pigment Red 264, C. I. Pigment Blue 15:4, C. I. Pigment Blue 15:6, and C. I. Pigment Blue 16 are pigments satisfying the following requirement 1.

Requirement 1)

In a case where a film having a thickness of 0.60 μm is formed by heating, at 200° C. for 30 minutes, a composition which includes 6 mass % of a pigment, 10 mass % of a resin B-5, and 84 mass % of propylene glycol monomethyl ether acetate, in a case where the film is subjected to a heating treatment at 300° C. for 5 hours in a nitrogen atmosphere, the rate of change ΔA10 in an absorbance of the film after the heating treatment, which is represented by Expression (10), is 50% or less;

ΔA10=|100−(A12/A11)×100| (10)

ΔA10 is the rate of change in the absorbance of the film after the heating treatment;

A11 is the maximum value of the absorbance of the film before the heating treatment in a wavelength range of 400 to 1100 nm;

A12 is the absorbance of the film after the heating treatment, and is the absorbance at the wavelength showing the maximum value of the film before the heating treatment in a wavelength range of 400 to 1100 nm; and

The resin B-5 is a resin having the following structure, in which a numerical value added to a main chain represents a molar ratio, the weight-average molecular weight is 11000, and the acid value is 32 mgKOH/g.

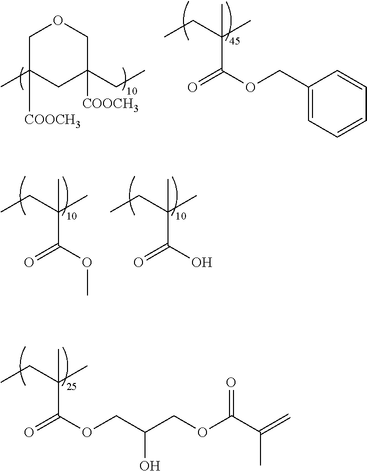

(Pigment Derivative)

Derivative 1: compound having the following structure

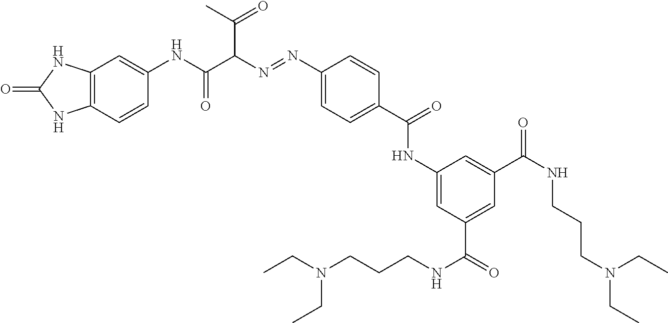 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Derivative 2: compound having the following structure (in the following structural formula, Me represents a methyl group and Ph represents a phenyl group)

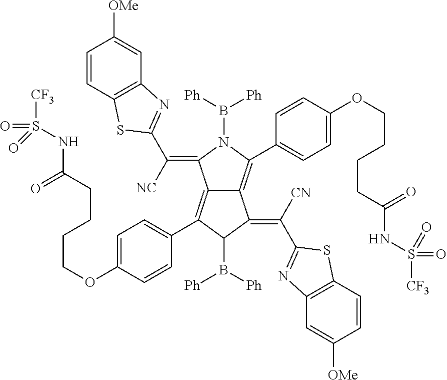 [SMILES: COc1ccc2sc(/C(C#N)=c3/c4c(c(-c5ccc(OCCCCC(=O)NS(=O)(=O)C(F)(F)F)cc5)n3B(c3ccccc3)c3ccccc3)/C(=C(\C#N)c3nc5cc(OC)ccc5s3)C(B(c3ccccc3)c3ccccc3)C=4c3ccc(OCCCCC(=O)NS(=O)(=O)C(F)(F)F)cc3)nc2c1]

(Resin (Dispersant))

B-1: resin having the following structure ((meth)acrylic resin, a numerical value added to a main chain represents a molar ratio, and a numerical value added to a side chain represents the number of repeating units; weight-average molecular weight: 20000, acid value: 77 mgKOH/g)

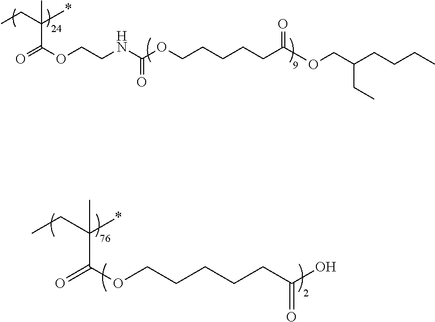

B-2: resin having the following structure (weight-average molecular weight=12000, acid value: 195.4 mgKOH/g, amine value: 0 mgKOH/g, numerical value added to a main chain represents a molar ratio of a repeating unit)

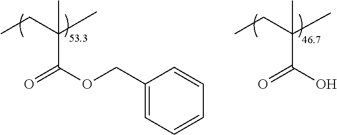

B-3: resin having the following structure ((meth)acrylic resin, a numerical value added to a main chain represents a molar ratio; weight-average molecular weight: 14000, acid value: 79.3 mgKOH/g)

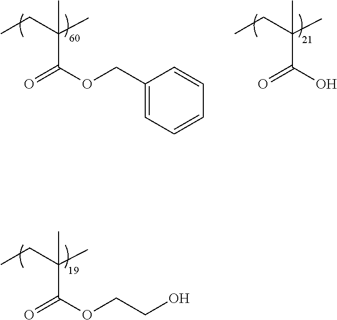

B-4: resin having the following structure ((meth)acrylic resin, a numerical value added to a main chain represents a molar ratio, and a numerical value added to a side chain represents the number of repeating units; weight-average molecular weight: 24000, acid value: 52.5 mgKOH/g)

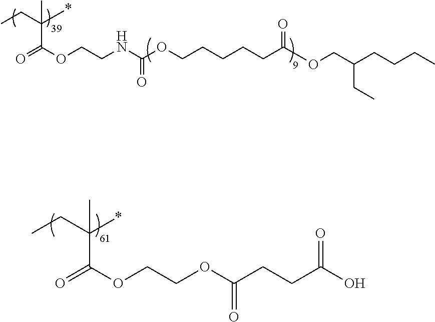

B-5: resin having the following structure ((meth)acrylic resin, a numerical value added to a main chain represents a molar ratio; weight-average molecular weight: 11000, acid value: 32 mgKOH/g)

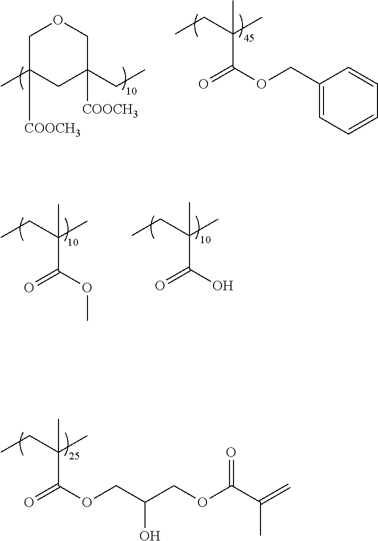

B-14: resin having the following structure ((meth)acrylic resin, a numerical value added to a main chain represents a molar ratio, and a numerical value added to a side chain represents the number of repeating units; weight-average molecular weight: 21000, acid value: 77 mgKOH/g)

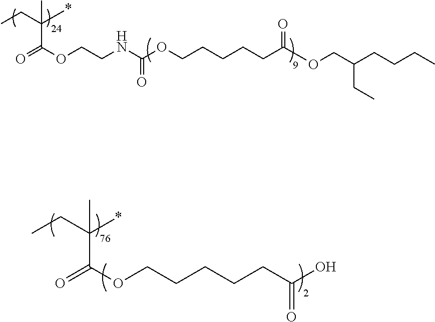

B-15: resin having the following structure (polyimine resin, a numerical value added to a main chain represents a molar ratio, and a numerical value added to a side chain represents the number of repeating units; weight-average molecular weight: 21000)

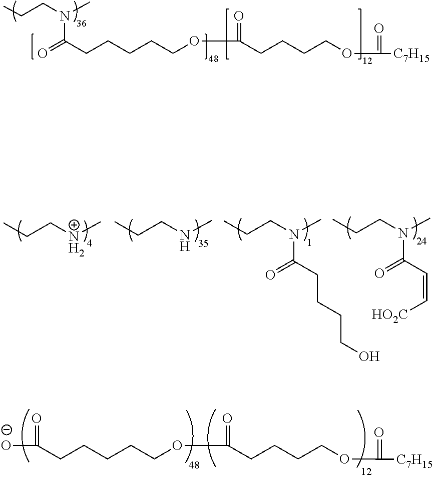

(Solvent)

S-1: propylene glycol monomethyl ether acetate

S-2: propylene glycol monomethyl ether

S-3: cyclohexanone

<Production of Resin Composition>

The following raw materials were mixed to prepare a resin composition. The unit of the numerical value in the column of the amount added described in the tables below is parts by mass. The ratio of the pigment in the total solid content of the resin composition, the ratio of the pigment in the total solid content of the resin composition, and the ratio of the resin A in components in which the coloring material is excepted from the total solid content of the resin composition are also described.

TABLE 2

| | Example 1 | | Example 2 | | Example 3 | | Example 4 | | Example 5 | |
|---|---|---|---|---|---|---|---|---|---|---|
| | | Blended | | Added | | Added | | Added | | Added |
| | Type | amount | Type | amount | Type | amount | Type | amount | Type | amount |
| Dispersion liquid | R1 | 45.71 | B1 | 40.42 | B2 | 57.97 | B3 | 41.03 | B1 | 20.21 |
| Dye | | | | | | | | | | |
| Resin (resin A) | B-12 | 16.33 | B-12 | 16.33 | B-12 | 16.33 | B-12 | 16.33 | B-7 | 8 |
| Resin (other resin) | | | | | | | | | | |
| Polymerizable compound | | | | | | | | | | |
| Photopolymerization initiator | D-2 | 0.32 | D-2 | 0.32 | D-2 | 0.32 | D-2 | 0.32 | | |
| Surfactant | | | | | | | | | | |
| Solvent | S-1 | 37.64 | S-1 | 42.93 | S-1 | 25.38 | S-1 | 42.32 | S-4 | 71.79 |

| | | | | | |
|---|---|---|---|---|---|
| Total solid content (mass %) | 16.32 | 16.32 | 16.32 | 16.32 | 12.00 |
| of resin composition | | | | | |
| Ratio (mass %) of coloring | 29.13 | 32.69 | 38.36 | 32.68 | 22.23 |
| material in total solid content | | | | | |
| of resin composition | | | | | |
| Ratio (mass %) of resin A in | 69.18 | 72.84 | 79.53 | 72.82 | 85.73 |
| components in which coloring | | | | | |
| material is excepted from total | | | | | |
| solid content of resin | | | | | |
| composition | | | | | |

TABLE 3

| | Example 6 | | Example 7 | | Example 8 | | Example 9 | | Example 10 | |
|---|---|---|---|---|---|---|---|---|---|---|
| | | Added | | Added | | Added | | Added | | Added |
| | Type | amount | Type | amount | Type | amount | Type | amount | Type | amount |
| Dispersion liquid | B1 | 20.21 | B1 | 40.42 | B1 | 40.42 | B1 | 40.42 | B1 | 46.81 |
| Dye | | | | | | | | | | |
| Resin (resin A) | B-8 | 8 | B-9 | 13.33 | B-10 | 16.33 | B-11 | 8 | B-12 | 16.33 |
| Resin (other resin) | | | | | | | | | | |
| Polymerizable compound | | | | | | | | | C-1 | 1.88 |
| Photopolymerization | | | | | D-2 | 0.08 | D-2 | 0.08 | D-1 | 0.99 |
| initiator | | | | | | | | | | |
| Surfactant | | | | | | | | | E-1 | 0.1 |
| Solvent | S-5 | 71.79 | S-1 | 46.25 | S-1 | 43.17 | S-1 | 51.5 | S-1 | 33.89 |

| | | | | | |
|---|---|---|---|---|---|
| Total solid content (mass %) | 12.00 | 16.00 | 21.16 | 16.08 | 20.24 |
| of resin composition | | | | | |
| Ratio (mass %) of coloring | 22.23 | 33.35 | 25.22 | 33.18 | 30.54 |
| material in total solid | | | | | |
| content of resin composition | | | | | |
| Ratio (mass %) of resin A in | 85.73 | 75.02 | 82.66 | 74.46 | 56.93 |
| components in which | | | | | |
| coloring material is excepted | | | | | |
| from total solid content of | | | | | |
| resin composition | | | | | |

TABLE 4

| | Example 11 | | Example 12 | | Example 13 | | Comparative example 1 | |
|---|---|---|---|---|---|---|---|---|
| | | Added | | Added | | Added | | Added |
| | Type | amount | Type | amount | Type | amount | Type | amount |
| Dispersion liquid | R2 | 45.71 | BK | 52.55 | B1 | 10 | B4 | 43.49 |
| | | | IR | 28.58 | | | | |
| Dye | | | | | | | | |
| Resin (resin A) | B-12 | 16.33 | B-12 | 11.48 | B-8 | 16 | B-13 | 4 |
| Resin (other resin) | | | | | | | B-5 | 12.33 |
| Polymerizable compound | | | | | | | | |
| Photopolymerization initiator | D-2 | 0.32 | D-2 | 0.25 | | | D-2 | 0.32 |
| Surfactant | | | | | | | | |
| Solvent | S-1 | 37.64 | S-1 | 7.14 | S-5 | 74 | S-1 | 39.86 |

| | | | | |
|---|---|---|---|---|
| Total solid content (mass %) of | 16.32 | 23.55 | 17.98 | 15.21 |
| resin composition | | | | |
| Ratio (mass %) of coloring | 32.49 | 49.03 | 7.34 | 31.44 |
| material in total solid content of | | | | |
| resin composition | | | | |
| Ratio (mass %) of resin A in | 72.62 | 46.86 | 96.04 | 18.79 |
| components in which coloring | | | | |
| material is excepted from total | | | | |
| solid content of resin composition | | | | |

Among the raw materials listed in the above tables, details of the raw materials shown by abbreviations are as follows.

(Dispersion Liquid)

Dispersion liquid R1, R2, B1, B2, B3, B4, BK, IR: dispersion liquids R1, R2, B1, B2, B3, B4, BK, and IR described above

(Resin)

B-5: resin B-5 described above

B-7: resin having the following structure (polybenzoxazole precursor, weight-average molecular weight: 21000, solid content: 100%)

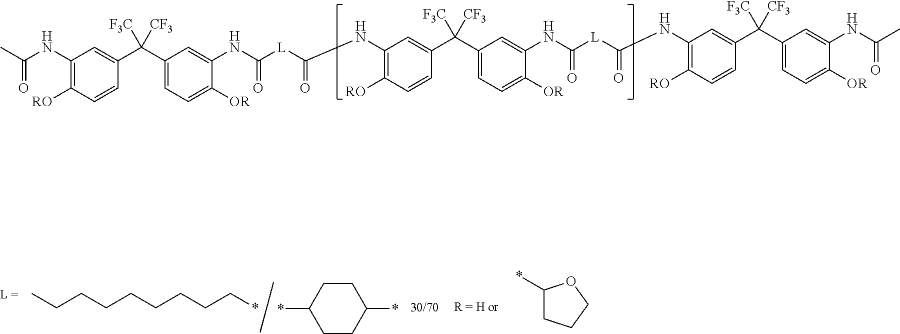

B-8: resin having the following structure (polyimide precursor, weight-average molecular weight: 24000, solid content: 100%)

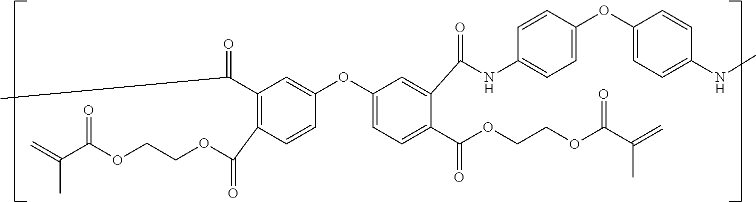

B-9: polyester-modified silicone resin (KR-5230, manufactured by Shin-Etsu Chemical Co., Ltd., solid content: 60%)

B-10: resin having the following structure (epoxy resin, Techmore VG3101M80, manufactured by Printec Co., solid content: 80.1%)

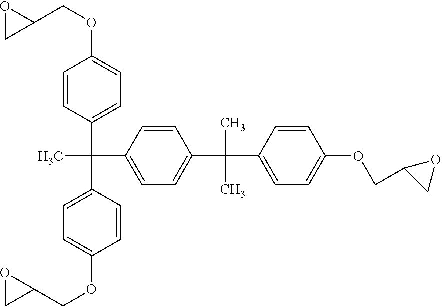 [SMILES: CC(C)(c1ccc(OCC2CO2)cc1)c1ccc(C(C)(c2ccc(OCC3CO3)cc2)c2ccc(OCC3CO3)cc2)cc1]

B-11: bismaleimide resin (HR3070, manufactured by Printec Co., solid content: 100%)

B-12: resin having the following structure (epoxy-modified silicone resin, COMPOCERAN E103D, manufactured by Arakawa Chemical Industries, Ltd., solid content: 49%)

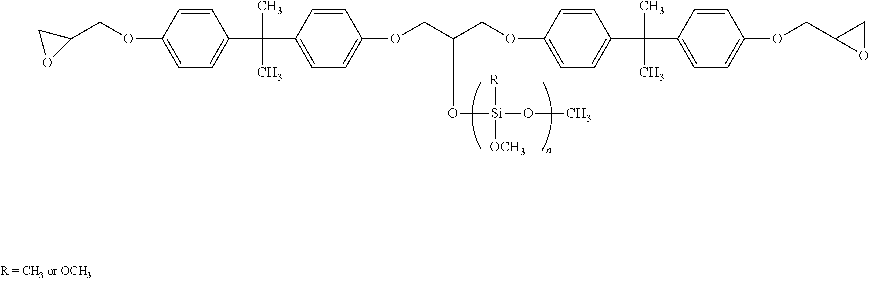

B-13: epoxy resin (DENACOL EX-611, manufactured by Nagase ChemteX Corporation)

With regard to the resins B-7 to B-12, in a case where the resins B-7 to B-12 were applied to a glass substrate and heated at 100° C. for 120 seconds to form a film having a thickness of 0.60 μm, a minimum value of a transmittance of the film at a wavelength of 400 to 1100 nm was 70% or more.

(Polymerizable Compound)

C-1: compound having the following structure

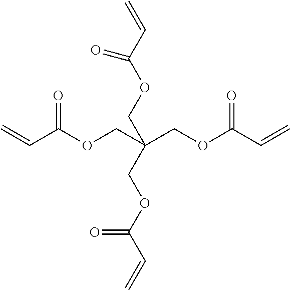 [SMILES: C=CC(=O)OCC(COC(=O)C=C)(COC(=O)C=C)COC(=O)C=C]

(Photopolymerization Initiator)

D-1: compound having the following structure

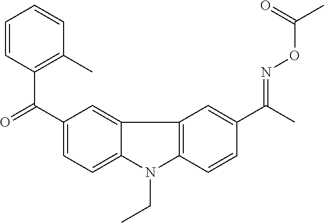 [SMILES: CCn1c2ccc(C(=O)c3ccccc3C)cc2c2cc(/C(C)=N/OC(C)=O)ccc21]

D-2: compound having the following structure

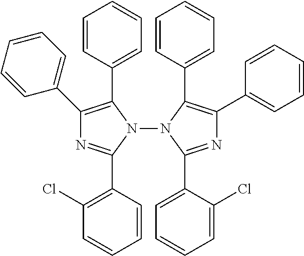 [SMILES: Clc1ccccc1-c1nc(-c2ccccc2)c(-c2ccccc2)n1-n1c(-c2ccccc2Cl)nc(-c2ccccc2)c1-c1ccccc1]

(Surfactant)

E-1: compound having the following structure (Mw=14000; a numerical value “%” representing the proportion of a repeating unit is mol %, fluorine-based surfactant)

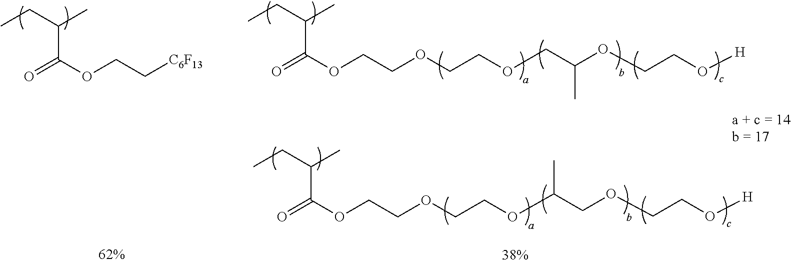

(Solvent)

S-1: propylene glycol monomethyl ether acetate

S-4: γ-butyrolactone

S-5: N-methyl-2-pyrrolidone

<Evaluation>

(ΔA)

The resin composition was applied to a glass substrate by spin coating, and dried (pre-baked) at 100° C. for 120 seconds using a hot plate. Thereafter, the resin composition was heated (post-baked) at 200° C. for 30 minutes using an oven to produce a film having a thickness of 0.60 μm. The film thickness was appropriately adjusted to have a thickness of 0.60 μm according to the rotation speed and sequence of the spin coating. The film thickness was measured by scraping a part of the film to expose a surface of the glass substrate, and measuring a step (film thickness of the coating film) between the surface of the glass substrate and the coating film using a stylus type step meter (DektakXT, manufactured by BRUKER). The film thickness and spectroscopy were measured in a state in which the substrate temperature was set to room temperature (22° C.) in a laboratory where the temperature and humidity were controlled to 22±5° C. and 60±20%. The absorbance of the obtained film in a wavelength range of 400 to 1100 nm was measured. Next, the obtained film was heat-treated at 300° C. for 5 hours in a nitrogen atmosphere. The absorbance of the film after the heating treatment in a wavelength range of 400 to 1100 nm was measured. From Expression (1), the rate of change ΔA in an absorbance of the film after the heating treatment was obtained.

ΔA=|100−(A2/A1)×100| (1)

ΔA is the rate of change in the absorbance of the film after the heating treatment;

A1 is the maximum value of the absorbance of the film before the heating treatment in a wavelength range of 400 to 1100 nm; and

A2 is the absorbance of the film after the heating treatment, and is the absorbance at a wavelength showing the maximum value of the absorbance of the film before the heating treatment in a wavelength range of 400 to 1100 nm.

(Δλ)

The resin composition was applied to a glass substrate by spin coating, and dried (pre-baked) at 100° C. for 120 seconds using a hot plate. Thereafter, the resin composition was heated (post-baked) at 200° C. for 30 minutes using an oven to produce a film having a thickness of 0.60 μm. The absorbance of the obtained film in a wavelength range of 400 to 1100 nm was measured, and a wavelength λ1 showing the maximum value of the absorbance was measured. Next, the obtained film was heat-treated at 300° C. for 5 hours in a nitrogen atmosphere. The absorbance of the film after the heating treatment in a wavelength range of 400 to 1100 nm was measured, and a wavelength λ2 showing the maximum value of the absorbance was measured.

The absolute value Δλ of the difference between λ1 and λ2 was calculated.

(ΔAmax)

The resin composition was applied to a glass substrate by spin coating, and dried (pre-baked) at 100° C. for 120 seconds using a hot plate. Thereafter, the resin composition was heated (post-baked) at 200° C. for 30 minutes using an oven to produce a film having a thickness of 0.60 μm. The absorbance of the obtained film in a wavelength range of 400 to 1100 nm was measured. Next, the obtained film was heat-treated at 300° C. for 5 hours in a nitrogen atmosphere. The absorbance of the film after the heating treatment in a wavelength range of 400 to 1100 nm was measured. Using the absorbance spectrum of the film before and after the heating treatment in a wavelength range of 400 to 1100 nm, the maximum value ΔAmax of the rate of change in the absorbance of the film after the heating treatment in the wavelength range of 400 to 1100 nm was calculated. The rate of change in the absorbance is a value calculated from Expression (2).

ΔA_{λ}=|100−(A2_{λ}/A1_{λ})×100| (2)

ΔA_{λ} is the rate of change in the absorbance of the film after the heating treatment at a wavelength λ;

A1_{λ} is the absorbance of the film before the heating treatment at the wavelength λ; and

A2_{λ} is the absorbance of the film after the heating treatment at the wavelength λ.

(Cracks)

The resin composition was applied to a glass substrate by spin coating, and dried (pre-baked) at 100° C. for 120 seconds using a hot plate. Thereafter, the resin composition was heated (post-baked) at 200° C. for 30 minutes using an oven to produce a film having a thickness of 0.60 μm.

Next, SiO₂ was laminated at 200 nm on the surface of the obtained film by a sputtering method to form an inorganic film. The obtained film in which the inorganic film was formed on the surface was heat-treated at 300° C. for 5 hours in a nitrogen atmosphere. The surface of the inorganic film after the heating treatment was observed with an optical microscope to evaluate the presence or absence of cracks.

TABLE 5

| | ΔA | Δλ | ΔAmax | Cracks |
|---|---|---|---|---|
| Example 1 | 36% | 5 nm | 36% | No cracks |
| Example 2 | 13% | 20 nm | 13% | No cracks |
| Example 3 | 10% | 18 nm | 10% | No cracks |
| Example 4 | 14% | 19 nm | 14% | No cracks |
| Example 5 | 13% | 20 nm | 13% | No cracks |
| Example 6 | 13% | 20 nm | 13% | No cracks |
| Example 7 | 13% | 20 nm | 13% | No cracks |
| Example 8 | 13% | 20 nm | 45% | No cracks |
| Example 9 | 13% | 20 nm | 48% | No cracks |
| Example 10 | 13% | 20 nm | 13% | No cracks |
| Example 11 | 34% | 6 nm | 34% | No cracks |
| Example 12 | 42% | 22 nm | 42% | No cracks |
| Example 13 | 13% | 20 nm | 13% | No cracks |
| Comparative | 62% | 11 nm | 62% | Cracks |
| example 1 | | | | |

All of the resin compositions of Examples had a rate of change in the absorbance of 50% or less. Therefore, as compared with the resin composition of Comparative Example 1, it was possible to expand a process window of process after manufacturing the film. In addition, in a case where the resin compositions of Examples were used, no crack was generated in the inorganic film in the evaluation of cracks.

### (Example 100) Pattern Formation by Photolithography Method

On a silicon wafer, the resin composition of Example 10 was applied to a glass substrate by spin coating, and dried (pre-baked) at 100° C. for 120 seconds using a hot plate. Thereafter, the resin composition was heated (post-baked) at 200° C. for 30 minutes using an oven to form a resin composition layer having a thickness of 0.60 μm.

Next, using an i-ray stepper exposure device FPA-3000 i5+(manufactured by Canon Inc.), the resin composition layer was irradiated with light having a wavelength of 365 nm through a mask pattern in which each of the square pixels with a side length of 1.1 μm was arranged on the substrate in a region of 4 mm×3 mm to perform exposure thereon with an exposure amount of 500 mJ/cm².

Next, the silicon wafer on which the resin composition layer after the exposure was formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 rpm, the silicon wafer was rinsed by supplying pure water from above the center of rotation in shower-like from an ejection nozzle, and then spray-dried to form a pattern (pixel).

In a case where the cross section of the produced resist pattern was observed with a scanning electron microscope (SEM), pixels having a film thickness of 0.6 μm and a width of 1.1 μm were formed.

What is claimed is:

1. A resin composition comprising:
a coloring material;
a resin; and
a solvent,
wherein, in a case where a film having a thickness of 0.60 μm is formed by heating the resin composition at 200° C. for 30 minutes, a rate of change ΔA in an absorbance of the film after performing a heating treatment of the film at 300° C. for 5 hours in a nitrogen atmosphere, which is represented by Expression (1), is 50% or less,
ΔA=|100−(A2/A1)×100| (1)
ΔA is the rate of change in the absorbance of the film after the heating treatment;
A1 is a maximum value of an absorbance of the film before the heating treatment in a wavelength range of 400 to 1100 nm; and
A2 is an absorbance of the film after the heating treatment, and is an absorbance at a wavelength showing the maximum value of the absorbance of the film before the heating treatment in a wavelength range of 400 to 1100 nm.

2. The resin composition according to claim 1,
wherein, in the case where a film having a thickness of 0.60 μm is formed by heating the resin composition at 200° C. for 30 minutes, an absolute value of a difference between a wavelength λ1 showing the maximum value of the absorbance of the film in a wavelength range of 400 to 1100 nm and a wavelength λ2 showing the maximum value of the absorbance of the film after the heating treatment at 300° C. for 5 hours in a nitrogen atmosphere is 50 nm or less.

3. The resin composition according to claim 1,
wherein, in the case where a film having a thickness of 0.60 μm is formed by heating the resin composition at 200° C. for 30 minutes, a maximum value of the rate of change in an absorbance of the film after the heating treatment at 300° C. for 5 hours in a nitrogen atmosphere in a wavelength range of 400 to 1100 nm is 30% or less.

4. The resin composition according to claim 1,
wherein a content of the coloring material in a total solid content of the resin composition is 5 mass % or more.

5. The resin composition according to claim 1,
wherein the coloring material is an organic pigment.

6. The resin composition according to claim 1,
wherein the coloring material includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment.

7. The resin composition according to claim 1,
wherein the coloring material includes two or more chromatic coloring materials and a near-infrared absorbing coloring material, or includes a black pigment and a near-infrared absorbing coloring material.

8. The resin composition according to claim 1,
wherein the coloring material includes at least one selected from C. I. Pigment Red 264 or C. I. Pigment Blue 16.

9. The resin composition according to claim 1,
wherein the resin includes at least one resin A selected from a polyimide resin, a polybenzoxazole resin, an epoxy resin, a bismaleimide resin, a silicone resin, a polyarylate resin, a benzoxazine resin, or a precursor of these resins.

10. The resin composition according to claim 9,
wherein the resin A is at least one selected from a polyimide resin, a polybenzoxazole resin, or a precursor of these resins.

11. The resin composition according to claim 9,
wherein, in a case where the resin A is applied to a glass substrate and heated at 100° C. for 120 seconds to form a film having a thickness of 0.60 μm, a minimum value of a transmittance of the film at a wavelength of 400 to 1100 nm is 70% or more.

12. The resin composition according to claim 9,
wherein the resin A is included in an amount of 20 mass % or more in components in which the coloring material is excepted from a total solid content of the resin composition.

13. The resin composition according to claim 1,
wherein the resin includes an alkali-soluble resin.

14. The resin composition according to claim 1, further comprising:
a photopolymerization initiator.

15. The resin composition according to claim 1,
wherein, in a case where the resin composition is applied to a glass substrate and heated at 100° C. for 120 seconds to form a film having a film thickness of 0.6 μm, a maximum value of a transmittance of the film at a wavelength of 400 to 1100 nm is 70% or more, and a minimum value thereof is 30% or less.

16. A film obtained from the resin composition according to claim 1.

17. A color filter comprising:
the film according to claim 16.

18. A solid-state imaging element comprising:
the film according to claim 16.

19. An image display device comprising:
the film according to claim 16.
